(19) United States
(12) Patent Application Publication
(10) Pub. No.: US 2025/0377385 A1
(43) Pub. Date: Dec. 11, 2025

(54) MAGNETIC SENSOR

(71) Applicant: TDK CORPORATION, Tokyo (JP)

(72) Inventors: Hidekazu KOJIMA, Tokyo (JP); Hirokazu TAKAHASHI, Tokyo (JP); Takashi SAITO, Tokyo (JP); Satoshi MIURA, Tokyo (JP)

(73) Assignee: TDK CORPORATION, Tokyo (JP)

(21) Appl. No.: 19/204,753

(22) Filed: May 12, 2025

(30) Foreign Application Priority Data
Jun. 6, 2024 (JP) 2024-092231

(51) Int. Cl. G01R 15/20; G01C 17/28; G01R 19/00

(52) U.S. Cl. CPC G01R 15/205; G01C 17/28; G01R 19/0092

(57) ABSTRACT

A magnetic sensor includes an MR element and a magnetic field generator that are disposed on an inclined surface. The magnetic field generator includes a ferromagnetic portion formed of a ferromagnetic material, and an antiferromagnetic portion formed of an antiferromagnetic material and exchange-coupled with the ferromagnetic portion. The ferromagnetic portion and the antiferromagnetic portion are stacked together in a direction intersecting the inclined surface. An angle that the inclined surface forms with respect to a top surface of a substrate at an any given point on the inclined surface changes depending on a position of the any given point in a direction perpendicular to the top surface of the substrate.

### CROSS REFERENCE TO RELATED APPLICATIONS

This application claims the benefit of Japanese Priority Patent Application No. 2024-092231 filed on Jun. 6, 2024, the entire contents of which are incorporated herein by reference.

### BACKGROUND

The disclosure relates to a magnetic sensor configured to be capable of applying a bias magnetic field to a magnetic detection element disposed on an inclined surface.

Magnetic sensors have been used for various applications in recent years. Examples of known magnetic sensors include one that uses a spin-valve magnetoresistive element provided on a substrate. The spin-valve magnetoresistive element includes a magnetization pinned layer whose magnetization direction is fixed, a free layer whose magnetization direction is variable depending on a direction of a magnetic field applied thereto, and a gap layer disposed between the magnetization pinned layer and the free layer. In many cases, the spin-valve magnetoresistive element provided on the substrate is configured to have a sensitivity to a magnetic field in a direction parallel to a surface of the substrate. Therefore, such a magnetoresistive element is suitable for detecting a magnetic field whose direction changes in a plane parallel to the surface of the substrate.

Meanwhile, a system including a magnetic sensor may be intended to detect a magnetic field including a component in a direction perpendicular to a surface of a substrate by using a magnetoresistive element provided on the substrate. In such a case, the magnetic field including the component in the direction perpendicular to the surface of the substrate can be detected by disposing the magnetoresistive element on an inclined surface formed on the substrate.

Incidentally, some magnetic sensors include a means of applying a bias magnetic field to a magnetoresistive element. The bias magnetic field is used, for example, so that the magnetoresistive element responds linearly to a change in the strength of a target magnetic field, which is a magnetic field to be detected. In a magnetic sensor using a spin-valve magnetoresistive element, when there is no target magnetic field, the bias magnetic field is also used to make a free layer have a single magnetic domain and make the magnetization direction of the free layer direct to a certain direction.

JP 2006-261401A discloses a magnetic sensor in which a Z-axis sensor is provided on slopes of a plurality of projections on a substrate. Magnetoresistive elements constituting the Z-axis sensor each include a magneto-sensitive element provided along a longitudinal direction of the slope and a bias magnet portion that applies a bias magnetic field to the magneto-sensitive element.

JP 2016-176911 A discloses a magnetic sensor that includes a magnetoresistive element and two magnetic field generators with the magnetoresistive element interposed therebetween. Each of the magnetic field generators includes an antiferromagnetic layer and a ferromagnetic layer stacked together and is configured to apply a bias magnetic field to the magnetoresistive element.

The magnetic field generator disclosed in JP 2016-176911 A is capable of increasing a strength of the bias magnetic field generated by the magnetic field generator by increasing a volume of the magnetic field generator. However, as the magnetic sensor disclosed in JP 2006-261401 A, when the magnetic field generator is formed on an inclined surface, the volume of the magnetic field generator sometimes becomes smaller compared to a case where the magnetic field generator is formed on a plane. As a result, it is not possible to apply a bias magnetic field of sufficient strength to a magnetic detection element such as a magnetoresistive element in some cases.

### SUMMARY

A magnetic sensor according to one embodiment of the disclosure includes a support member having at least one inclined surface inclined with respect to a reference plane; at least one magnetic detection element disposed on the at least one inclined surface and configured to detect a target magnetic field; and at least one magnetic field generator disposed on the at least one inclined surface and configured to generate a magnetic field to be applied to the at least one magnetic detection element. The at least one magnetic field generator includes a ferromagnetic portion formed of a ferromagnetic material and an antiferromagnetic portion that is formed of an antiferromagnetic material and is exchange-coupled with the ferromagnetic portion. The ferromagnetic portion and the antiferromagnetic portion are stacked together in a direction intersecting the at least one inclined surface. An angle that the at least one inclined surface forms with respect to the reference plane at any given point on the at least one inclined surface changes depending on a position of the any given point in a direction perpendicular to the reference plane.

Other and further objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing a magnetic sensor device including a magnetic sensor according to a first example embodiment of the disclosure.

FIG. 2 is a plan view showing the magnetic sensor device shown in FIG. 1.

FIG. 3 is a side view showing the magnetic sensor device shown in FIG. 1.

FIG. 4 is a functional block diagram showing a configuration of the magnetic sensor device shown in FIG. 1.

FIG. 5 is a circuit diagram showing a circuit configuration of a first detection circuit of the first example embodiment of the disclosure.

FIG. 6 is a circuit diagram showing a circuit configuration of a second detection circuit of the first example embodiment of the disclosure.

FIG. 7 is a circuit diagram showing a circuit configuration of a third detection circuit of the first example embodiment of the disclosure.

FIG. 8 is a plan view showing a part of a first chip of the first example embodiment of the disclosure.

FIG. 9 is a sectional view showing a part of the first chip of the first example embodiment of the disclosure.

FIG. 10 is another sectional view showing a part of the first chip of the first example embodiment of the disclosure.

FIG. 11 is a plan view showing a part of a second chip of the first example embodiment of the disclosure.

FIG. 12 is a sectional view showing a part of the second chip of the first example embodiment of the disclosure.

FIG. 13 is another sectional view showing a part of the second chip of the first example embodiment of the disclosure.

FIG. 14 is a side view showing magnetoresistive elements and magnetic field generators of the first example embodiment of the disclosure.

FIG. 15 is a sectional view showing the magnetic field generator of the first example embodiment of the disclosure.

FIG. 16 is an explanatory diagram for describing a first example of layout of the plurality of magnetoresistive elements and the plurality of magnetic field generators of the first example embodiment of the disclosure.

FIG. 17 is an explanatory diagram for describing a second example of the layout of the plurality of magnetoresistive elements and the plurality of magnetic field generators of the first example embodiment of the disclosure.

FIG. 18 is a side view showing a first modification example of the magnetic field generator of the first example embodiment of the disclosure.

FIG. 19 is a side view showing a second modification example of the magnetic field generator of the first example embodiment of the disclosure.

FIG. 20 is a side view showing a third modification example of the magnetic field generator of the first example embodiment of the disclosure.

FIG. 21 is a side view showing a fourth modification example of the magnetic field generator of the first example embodiment of the disclosure.

FIG. 22 is a plan view showing magnetoresistive elements and magnetic field generators of a second example embodiment of the disclosure.

FIG. 23 is a side view showing magnetoresistive elements and magnetic field generators of a third example embodiment of the disclosure.

FIG. 24 is a plan view showing the magnetoresistive element and the magnetic field generators of the third example embodiment of the disclosure.

FIG. 25 is a plan view showing a magnetoresistive element and magnetic field generators of a fourth example embodiment of the disclosure.

FIG. 26 is a plan view showing a magnetoresistive element and magnetic field generators of a fifth example embodiment of the disclosure.

FIG. 27 is a perspective view showing a configuration of a current sensor system including a magnetic sensor according to a sixth example embodiment of the disclosure.

### DETAILED DESCRIPTION

An object of the disclosure is to provide a magnetic sensor capable of increasing a strength of a magnetic field to be applied to a magnetic detection element by a magnetic field generator.

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

### First Example Embodiment

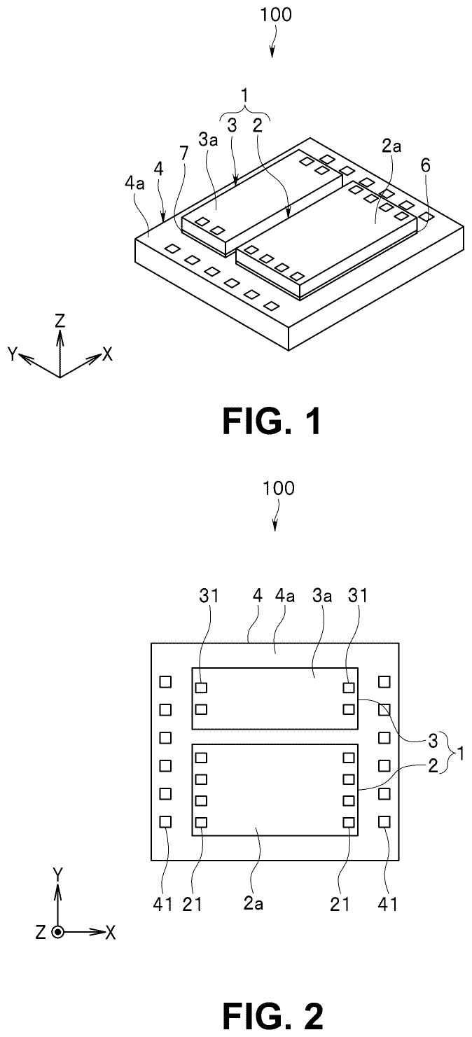

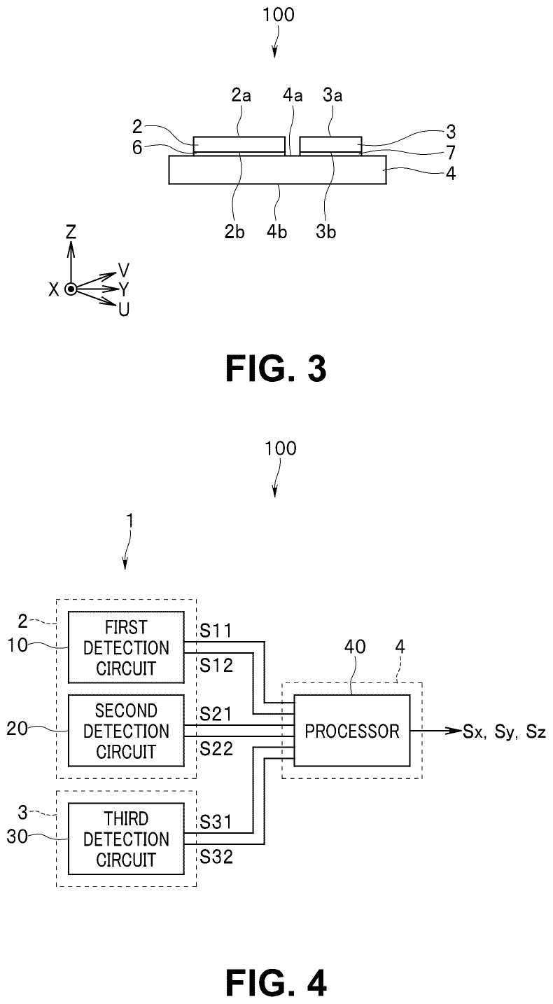

A configuration of a magnetic sensor device including a magnetic sensor according to a first example embodiment of the disclosure will initially be described with reference to FIGS. 1 to 4. FIG. 1 is a perspective view showing a magnetic sensor device 100. FIG. 2 is a plan view showing the magnetic sensor device 100. FIG. 3 is a side view showing the magnetic sensor device 100. FIG. 4 is a functional block diagram showing a configuration of the magnetic sensor device 100.

The magnetic sensor device 100 includes a magnetic sensor 1 according to the example embodiment. The magnetic sensor 1 includes a first chip 2 and a second chip 3. The magnetic sensor device 100 further includes a support 4 that supports the first and second chips 2 and 3. The first chip 2, the second chip 3, and the support 4 each have a rectangular parallelepiped shape. The support 4 has a reference plane 4a that is a top surface, a bottom surface 4b located opposite to the reference plane 4a, and four side surfaces connecting the reference plane 4a and the bottom surface 4b.

Now, a description will be given of a reference coordinate system in the example embodiment with reference to FIGS. 1 to 3. The reference coordinate system is an orthogonal coordinate system that is set with reference to the magnetic sensor device 100 and defined by three axes. An X direction, a Y direction, and a Z direction are defined in the reference coordinate system. The X, Y, and Z directions are orthogonal to one another. In particular, in the example embodiment, a direction that is perpendicular to the reference plane 4a of the support 4 and is directed from the bottom surface 4b to the reference plane 4a of the support 4 is referred to as the Z direction. The opposite directions to the X, Y, and Z directions will be expressed as −X, −Y, and −Z directions, respectively. The three axes defining the reference coordinate system are an axis parallel to the X direction, an axis parallel to the Y direction, and an axis parallel to the Z direction.

Hereinafter, the term “above” refers to positions located forward of a reference position in the Z direction, and “below” refers to positions opposite from the “above” positions with respect to the reference position. For each component of the magnetic sensor device 100, the term “top surface” refers to a surface of the component lying at the end thereof in the Z direction, and “bottom surface” refers to a surface of the component lying at the end thereof in the −Z direction. The expression “when seen in a specific direction (Z direction, for example)” means that the intended object is seen from a position at a distance in the specific direction or a direction parallel to the specific direction.

As shown in FIG. 3, a U direction and a V direction are defined as follows. The U direction is a direction rotated from the Y direction to the −Z direction. The V direction is a direction rotated from the Y direction to the Z direction. In particular, in the example embodiment, the U direction is a direction rotated from the Y direction to the −Z direction by α, and the V direction is a direction rotated from the Y direction to the Z direction by α. Note that α is an angle greater than 0° and smaller than 90°. A −U direction refers to a direction opposite to the U direction, and a −V direction refers to a direction opposite to the V direction. The U direction and V direction both are orthogonal to the X direction.

The first chip 2 has a top surface 2a and a bottom surface 2b that are located opposite to each other, and four side surfaces connecting the top surface 2a and the bottom surface 2b. The second chip 3 has a top surface 3a and a bottom surface 3b that are located opposite to each other, and four side surfaces connecting the top surface 3a and the bottom surface 3b.

The first chip 2 is mounted on the reference plane 4a in an orientation so that the bottom surface 2b of the first chip 2 faces the reference plane 4a of the support 4. The second chip 3 is mounted on the reference plane 4a in an orientation so that the bottom surface 3b of the second chip 3 faces the reference plane 4a of the support 4. The first chip 2 and the second chip 3 are bonded to the support 4 with, for example, adhesives 6 and 7, respectively.

The first chip 2 has a plurality of first electrode pads 21 provided on the top surface 2a. The second chip 3 has a plurality of second electrode pads 31 provided on the top surface 3a. The support 4 has a plurality of third electrode pads 41 provided on the reference plane 4a. Although not shown, in the magnetic sensor device 100, among the plurality of first electrode pads 21, the plurality of second electrode pads 31, and the plurality of third electrode pads 41, corresponding two electrode pads are connected to each other with bonding wires.

The magnetic sensor 1 includes a first detection circuit 10, a second detection circuit 20, and a third detection circuit 30. The first chip 2 includes the first detection circuit 10 and the second detection circuit 20. The second chip 3 includes the third detection circuit 30.

The magnetic sensor device 100 further includes a processor 40. The support 4 includes the processor 40. The first to third detection circuits 10, 20, and 30 and the processor 40 are connected via the plurality of first electrode pads 21, the plurality of second electrode pads 31, the plurality of third electrode pads 41, and a plurality of bonding wires.

The first to third detection circuits 10, 20, and 30 each include a plurality of magnetic detection elements, and are configured to detect a target magnetic field and generate at least one detection signal. In particular, in the example embodiment, the plurality of magnetic detection elements may be a plurality of magnetoresistive elements. The magnetoresistive elements will hereinafter be referred to as MR elements.

The processor 40 is configured to process the plurality of detection signals generated by the first to third detection circuits 10, 20, and 30 to generate a first detection value, a second detection value, and a third detection value. The first, second, and third detection values have a correspondence with components of the magnetic field in three respective different directions at a specific reference position. In particular, in the example embodiment, the foregoing three respective different directions are two directions parallel to an XY plane and a direction parallel to the Z direction. For example, the processor 40 is constructed of an application-specific integrated circuit (ASIC).

The target magnetic field may be the geomagnetism, for example. In such a case, the first, second, and third detection values have a correspondence with components of the geomagnetism in three respective different directions.

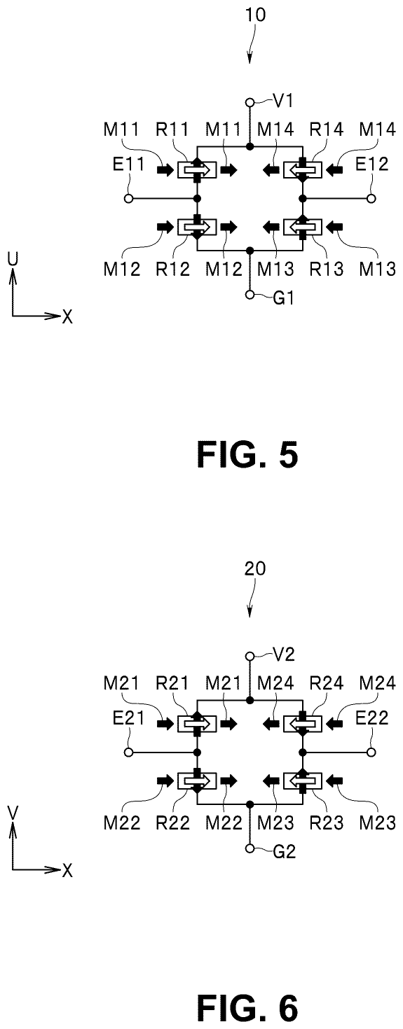

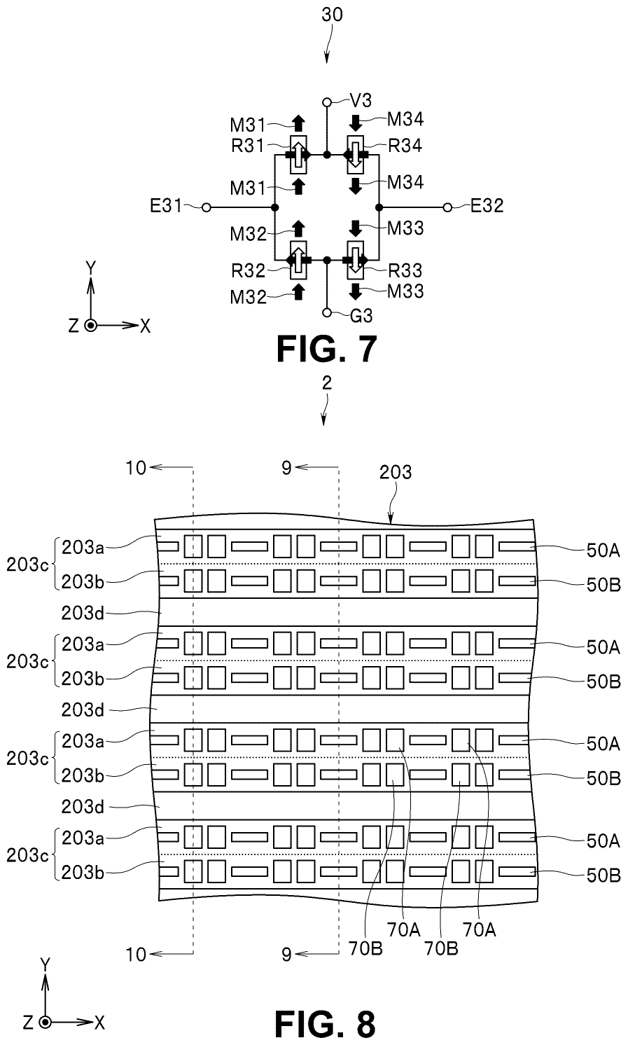

Next, circuit configurations of the first to third detection circuits 10, 20, and 30 will be described with reference to FIGS. 5 to 7. FIG. 5 is a circuit diagram showing a circuit configuration of the first detection circuit 10. FIG. 6 is a circuit diagram showing a circuit configuration of the second detection circuit 20. FIG. 7 is a circuit diagram showing a circuit configuration of the third detection circuit 30.

The first detection circuit 10 may be configured to detect a component of the target magnetic field in a direction parallel to the U direction and generate at least one first detection signal which has a correspondence with the component. The second detection circuit 20 may be configured to detect a component of the target magnetic field in a direction parallel to the V direction and generate at least one second detection signal which has a correspondence with the component. The third detection circuit 30 may be configured to detect a component of the target magnetic field in a direction parallel to the X direction and generate at least one third detection signal which has a correspondence with the component.

As shown in FIG. 5, the first detection circuit 10 may include a power supply port V1, a ground port G1, signal output ports E11 and E12, a first resistor section R11, a second resistor section R12, a third resistor section R13, and a fourth resistor section R14. The plurality of MR elements of the first detection circuit 10 constitute the first to fourth resistor sections R11, R12, R13, and R14.

The first resistor section R11 is provided between the power supply port V1 and the signal output port E11. The second resistor section R12 is provided between the signal output port E11 and the ground port G1. The third resistor section R13 is provided between the signal output port E12 and the ground port G1. The fourth resistor section R14 is provided between the power supply port V1 and the signal output port E12.

As shown in FIG. 6, the second detection circuit 20 may include a power supply port V2, a ground port G2, signal output ports E21 and E22, a first resistor section R21, a second resistor section R22, a third resistor section R23, and a fourth resistor section R24. The plurality of MR elements of the second detection circuit 20 constitute the first to fourth resistor sections R21, R22, R23, and R24.

The first resistor section R21 is provided between the power supply port V2 and the signal output port E21. The second resistor section R22 is provided between the signal output port E21 and the ground port G2. The third resistor section R23 is provided between the signal output port E22 and the ground port G2. The fourth resistor section R24 is provided between the power supply port V2 and the signal output port E22.

As shown in FIG. 7, the third detection circuit 30 may include a power supply port V3, a ground port G3, signal output ports E31 and E32, a first resistor section R31, a second resistor section R32, a third resistor section R33, and a fourth resistor section R34. The plurality of MR elements of the third detection circuit 30 constitute the first to fourth resistor sections R31, R32, R33, and R34.

The first resistor section R31 is provided between the power supply port V3 and the signal output port E31. The second resistor section R32 is provided between the signal output port E31 and the ground port G3. The third resistor section R33 is provided between the signal output port E32 and the ground port G3. The fourth resistor section R34 is provided between the power supply port V3 and the signal output port E32.

A voltage or current of specific magnitude is applied to each of the power supply ports V1 to V3. Each of the ground ports G1 to G3 is connected to the ground.

The plurality of MR elements of the first detection circuit 10 will hereinafter be referred to as a plurality of first MR elements 50A. The plurality of MR elements of the second detection circuit 20 will be referred to as a plurality of second MR elements 50B. The plurality of MR elements of the third detection circuit 30 will be referred to as a plurality of third MR elements 50C. Since the first to third detection circuits 10, 20, and 30 are components of the magnetic sensor 1, it can be said that the magnetic sensor 1 includes the plurality of first MR elements 50A, the plurality of second MR elements 50B, and the plurality of third MR elements 50C. Any given MR element will be denoted by the reference numeral 50.

Each MR element 50 may be a spin-valve MR element or an anisotropic magnetoresistive (AMR) element. In particular, in the example embodiment, each MR element 50 is a spin-valve MR element. The MR element 50 may include a magnetization pinned layer whose magnetization direction is fixed, a free layer whose magnetization direction is variable depending on the direction of a target magnetic field, and a gap layer located between the magnetization pinned layer and the free layer. The MR element 50 may be a tunnel magnetoresistive (TMR) element or a giant magnetoresistive (GMR) element. In the TMR element, the gap layer is a tunnel barrier layer. In the GMR element, the gap layer is a nonmagnetic conductive layer. The resistance of the MR element 50 changes with the angle that the magnetization direction of the free layer forms with respect to the magnetization direction of the magnetization pinned layer. The resistance of the MR element 50 is at its minimum value when the foregoing angle is 0°, and at its maximum value when the foregoing angle is 180°. In each MR element 50, the free layer has a shape anisotropy in which the direction of the magnetization easy axis is orthogonal to the magnetization direction of the magnetization pinned layer.

In FIGS. 5 to 7, the plurality of solid arrows overlapping with the respective resistor sections indicate the magnetization directions of the magnetization pinned layers of the MR elements 50. The plurality of hollow arrows overlapping with the respective resistor sections indicate the magnetization directions of the free layers of the MR elements 50 when no target magnetic field is applied to the MR elements 50.

In the example shown in FIG. 5, the magnetization directions of the magnetization pinned layers in each of the first and third resistor sections R11 and R13 are the U direction. The magnetization directions of the magnetization pinned layers in each of the second and fourth resistor sections R12 and R14 are the −U direction. The free layer in each of the plurality of first MR elements 50A has a shape anisotropy in which the direction of the magnetization easy axis is a direction parallel to the X direction. The magnetization directions of the free layers in each of the first and second resistor sections R11 and R12 in a case where no target magnetic field is applied to the first MR elements 50A are the X direction. The magnetization directions of the free layers in each of the third and fourth resistor sections R13 and R14 in the foregoing case are the −X direction.

In the example shown in FIG. 6, the magnetization directions of the magnetization pinned layers in each of the first and third resistor sections R21 and R23 are the V direction. The magnetization directions of the magnetization pinned layers in each of the second and fourth resistor sections R22 and R24 are the −V direction. The free layer in each of the plurality of second MR elements 50B has a shape anisotropy in which the direction of the magnetization easy axis is a direction parallel to the X direction. The magnetization directions of the free layers in each of the first and second resistor sections R21 and R22 in a case where no target magnetic field is applied to the second MR elements 50B are the X direction. The magnetization directions of the free layers in each of the third and fourth resistor sections R23 and R24 in the foregoing case are the −X direction.

In the example shown in FIG. 7, the magnetization directions of the magnetization pinned layers in each of the first and third resistor sections R31 and R33 are the X direction. The magnetization directions of the magnetization pinned layers in each of the second and fourth resistor sections R32 and R34 are the −X direction. The free layer in each of the plurality of third MR elements 50C has a shape anisotropy in which the direction of the magnetization easy axis is a direction parallel to the Y direction. The magnetization directions of the free layers in each of the first and second resistor sections R31 and R32 in a case where no target magnetic field is applied to the third MR elements 50C are the Y direction. The magnetization directions of the free layers in each of the third and fourth resistor sections R33 and R34 in the foregoing case are the −Y direction.

The magnetic sensor 1 further includes at least one magnetic field generator that generates a magnetic field (bias magnetic field) to be applied to the at least one MR element 50. In particular, in the example embodiment, the at least one magnetic field generator includes a plurality of magnetic field generators. In FIG. 5, the arrows denoted by the reference numerals M11, M12, M13, and M14 indicate the directions of the magnetic fields applied to the plurality of first MR elements 50A by the plurality of magnetic field generators. In the first and second resistor sections R11 and R12, a magnetic field in the X direction is applied to the plurality of first MR elements 50A by the plurality of magnetic field generators. In the third and fourth resistor sections R13 and R14, a magnetic field in the −X direction is applied to the plurality of first MR elements 50A by the plurality of magnetic field generators.

In FIG. 6, the arrows denoted by the reference numerals M21, M22, M23, and M24 indicate the directions of the magnetic fields applied to the plurality of second MR elements 50B by the plurality of magnetic field generators. In the first and second resistor sections R21 and R22, a magnetic field in the X direction is applied to the plurality of second MR elements 50B by the plurality of magnetic field generators. In the third and fourth resistor sections R23 and R24, a magnetic field in the −X direction is applied to the plurality of second MR elements 50B by the plurality of magnetic field generators.

In FIG. 7, the arrows denoted by the reference numerals M31, M32, M33, and M34 indicate the directions of the magnetic fields applied to the plurality of third MR elements 50C by the plurality of magnetic field generators. In the first and second resistor sections R31 and R32, a magnetic field in the Y direction is applied to the plurality of third MR elements 50C by the plurality of magnetic field generators. In the third and fourth resistor sections R33 and R34, a magnetic field in the −Y direction is applied to the plurality of third MR elements 50C by the plurality of magnetic field generators.

Note that in view of factors such as the production accuracy of the MR elements 50 and the magnetic field generators, the magnetization directions of the magnetization pinned layers, the directions of the magnetization easy axes of the free layers, and the directions of the magnetic fields applied to the MR elements 50 by the plurality of magnetic field generators may be slightly different from the foregoing directions. The magnetization of the magnetic pinned layers may be configured to include magnetization components in the foregoing directions as their main components. In such a case, the magnetization directions of the magnetization pinned layers are the same or substantially the same as the foregoing directions.

Next, the first to third detection signals will be described. The first detection signal will initially be described with reference to FIG. 5. As the strength of the component of the target magnetic field in the direction parallel to the U direction changes, the resistance of each of the resistor sections R11 to R14 of the first detection circuit 10 changes either so that the resistances of the resistor sections R11 and R13 increase and the resistances of the resistor sections R12 and R14 decrease or so that the resistances of the resistor sections R11 and R13 decrease and the resistances of the resistor sections R12 and R14 increase. Thereby the electric potential of each of the signal output ports E11 and E12 changes. The first detection circuit 10 is configured to generate a signal corresponding to the electric potential of the signal output port E11 as a first detection signal S11, and generate a signal corresponding to the electric potential of the signal output port E12 as a first detection signal S12.

Next, the second detection signal will be described with reference to FIG. 6. As the strength of the component of the target magnetic field in the direction parallel to the V direction changes, the resistance of each of the resistor sections R21 to R24 of the second detection circuit 20 changes either so that the resistances of the resistor sections R21 and R23 increase and the resistances of the resistor sections R22 and R24 decrease or so that the resistances of the resistor sections R21 and R23 decrease and the resistances of the resistor sections R22 and R24 increase. Thereby the electric potential of each of the signal output ports E21 and E22 changes. The second detection circuit 20 is configured to generate a signal corresponding to the electric potential of the signal output port E21 as a second detection signal S21, and generate a signal corresponding to the electric potential of the signal output port E22 as a second detection signal S22.

Next, the third detection signal will be described with reference to FIG. 7. As the strength of the component of the target magnetic field in the direction parallel to the X direction changes, the resistance of each of the resistor sections R31 to R34 of the third detection circuit 30 changes either so that the resistances of the resistor sections R31 and R33 increase and the resistances of the resistor sections R32 and R34 decrease or so that the resistances of the resistor sections R31 and R33 decrease and the resistances of the resistor sections R32 and R34 increase. Thereby the electric potential of each of the signal output ports E31 and E32 changes. The third detection circuit 30 is configured to generate a signal corresponding to the electric potential of the signal output port E31 as a third detection signal S31, and generate a signal corresponding to the electric potential of the signal output port E32 as a third detection signal S32.

Next, an operation of the processor 40 will be described. The processor 40 is configured to generate the first detection value and the second detection value based on the first detection signals S11 and S12, and the second detection signals S21 and S22. The first detection value is a detection value corresponding to the component of the target magnetic field in the direction parallel to the Y direction. The second detection value is a detection value corresponding to the component of the target magnetic field in the direction parallel to the Z direction. Hereinafter, the first detection value is represented by the reference numeral Sy, and the second detection value is represented by the reference numeral Sz.

The processor 40 generates the first and second detection values Sy and Sz as follows, for example. First, the processor 40 generates a value S1 by an arithmetic including obtainment of a difference S11-S12 between the first detection signal S11 and the first detection signal S12, and generates a value S2 by an arithmetic including obtainment of a difference S21-S22 between the second detection signal S21 and the second detection signal S22. Next, the processor 40 calculates values S3 and S4 using the following expressions (1) and (2).

$$S 3 = ( S 2 + S 1 ) / ( 2 cos α ) \qquad ( 1 )$$

$$S 4 = ( S 2 - S 1 ) / ( 2 sin α ) \qquad ( 2 )$$

The first detection value Sy may be the value S3 itself, or may be a result of corrections, such as a gain adjustment and an offset adjustment, made to the value S3. In the same manner, the second detection value Sz may be the value S4 itself, or may be a result of corrections, such as a gain adjustment and an offset adjustment, made to the value S4.

The processor 40 is further configured to generate the third detection value based on the third detection signals S31 and S32. The third detection value is a detection value corresponding to the component of the target magnetic field in the direction parallel to the X direction. The third detection value will hereinafter be represented by the reference numeral Sx.

In the example embodiment, the processor 40 generates the third detection value Sx by an arithmetic including obtainment of a difference S31-S32 between the third detection signal S31 and the third detection signal S32. The third detection value Sx may be the difference S31-S32 itself, or may be a result of corrections, such as a gain adjustment and an offset adjustment, made to the difference S31-S32.

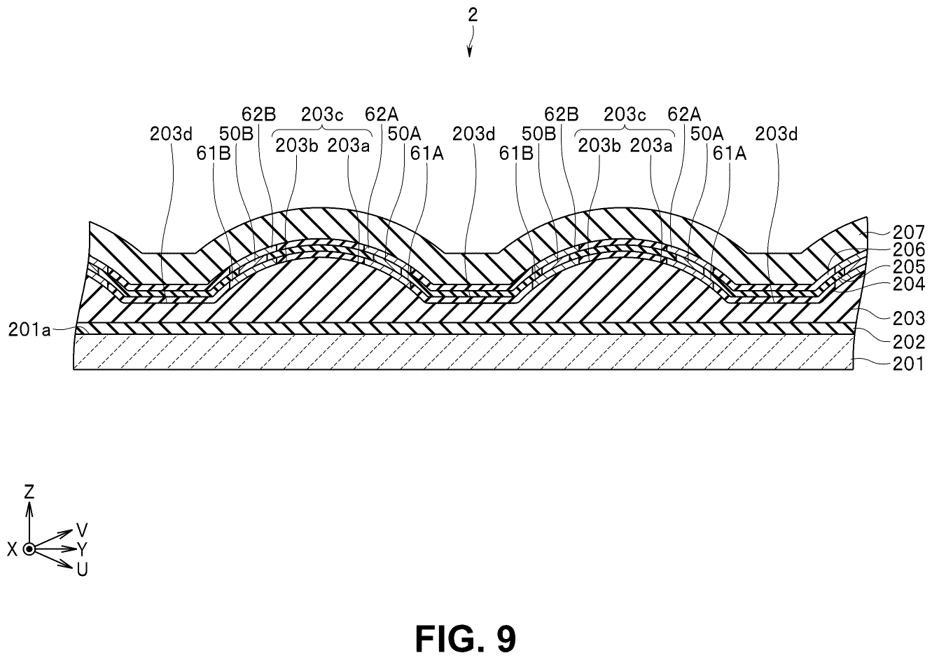

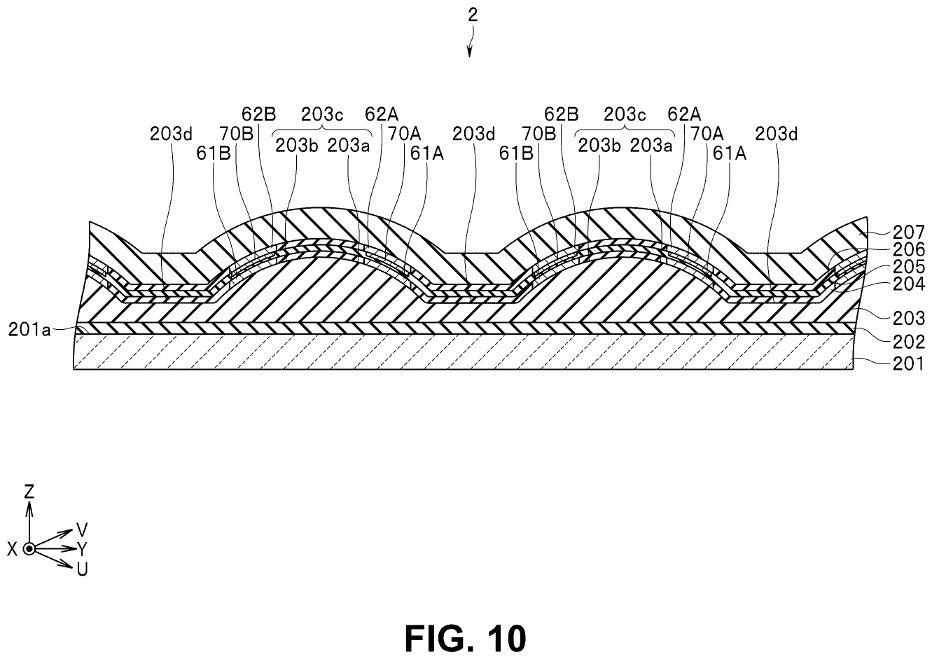

Next, a structure of the first chip 2 will be described in detail with reference to FIGS. 8 to 10. FIG. 8 is a plan view showing a part of the first chip 2. FIGS. 9 and 10 are sectional views each showing a part of the first chip 2. FIG. 9 shows a part of a cross section at the position indicated by the line 9-9 in FIG. 8. FIG. 10 shows a part of a cross section at the position indicated by the line 10-10 in FIG. 8.

The first chip 2 includes a substrate 201 having a top surface 201a, insulating layers 202, 203, 204, 205, 206, and 207, a plurality of lower electrodes 61A, a plurality of lower electrodes 61B, a plurality of upper electrodes 62A, a plurality of upper electrodes 62B, a plurality of first magnetic field generators 70A, and a plurality of second magnetic field generators 70B. The top surface 201a of the substrate 201 is parallel to the XY plane. The Z direction is also a direction perpendicular to the top surface 201a of the substrate 201.

The insulating layers 202 and 203 are disposed in this order on the substrate 201. The plurality of lower electrodes 61A and the plurality of lower electrodes 61B are disposed on the insulating layer 203. The insulating layer 204 is disposed, on the insulating layer 203, around the plurality of lower electrodes 61A and around the plurality of lower electrodes 61B. The plurality of first MR elements 50A are disposed on the plurality of lower electrodes 61A. The plurality of second MR elements 50B are disposed on the plurality of lower electrodes 61B. The insulating layer 205 is disposed, on the plurality of lower electrodes 61A, the plurality of lower electrodes 61B, and the insulating layer 204, around the plurality of first MR elements 50A and around the plurality of second MR elements 50B. The plurality of upper electrodes 62A are disposed on the plurality of first MR elements 50A and the insulating layer 205. The plurality of upper electrodes 62B are disposed on the plurality of second MR elements 50B and the insulating layer 205. The insulating layer 206 is disposed, on the insulating layer 205, around the plurality of upper electrodes 62A and around the plurality of upper electrodes 62B. The insulating layer 207 is disposed on the plurality of upper electrodes 62A, the plurality of upper electrodes 62B, and the insulating layer 206.

The plurality of first magnetic field generators 70A and the plurality of second magnetic field generators 70B are embedded in the insulating layer 205. Each of the plurality of first magnetic field generators 70A is located at distances from the first MR elements 50A and the lower electrodes 61A. Each of the plurality of second magnetic field generators 70B is located at distances from the second MR elements 50B and the lower electrodes 61B. The first chip 2 may include insulating films interposed respectively between each of the plurality of first magnetic field generators 70A and each of the plurality of first MR elements 50A, between each of the plurality of second magnetic field generators 70B and each of the plurality of second MR elements 50B, between each of the plurality of first magnetic field generators 70A and each of the plurality of lower electrodes 61A, and between each of the plurality of second magnetic field generators 70B and each of the plurality of lower electrodes 61B.

The top surface of each of the plurality of first magnetic field generators 70A may be in contact with the bottom surface of the upper electrode 62A. The top surface of each of the plurality of second magnetic field generators 70B may be in contact with the bottom surface of the upper electrode 62B.

The first chip 2 includes a support member that supports the plurality of first MR elements 50A and the plurality of second MR elements 50B. The support member has at least one inclined surface inclined with respect to the top surface 201a of the substrate 201. In particular, in the example embodiment, the support member includes the insulating layer 203.

The insulating layer 203 includes a plurality of protruding surfaces 203c each protruding in a direction (Z direction) away from the top surface 201a of the substrate 201. The plurality of protruding surfaces 203c each extend in the direction parallel to the X direction. The overall shape of each protruding surface 203c is a semicylindrical curved surface formed by moving the curved shape (arch shape) of the protruding surface 203c shown in FIGS. 9 and 10 along a direction parallel to the X direction. The plurality of protruding surfaces 203c are arranged in the direction parallel to the Y direction.

Now, focus is placed on any one of the plurality of protruding surfaces 203c. The protruding surface 203c may include a first inclined surface 203a and a second inclined surface 203b. The first inclined surface 203a is a surface forming a part of the protruding surface 203c on the side of the Y direction. The second inclined surface 203b is a surface forming a part of the protruding surface 203c on the side of the −Y direction. The first inclined surface 203a and the second inclined surface 203b may each have a shape long in the direction parallel to the X direction.

The top surface 201a of the substrate 201 is parallel to the XY plane. The reference plane 4a is parallel to the XY plane. The first inclined surface 203a and the second inclined surface 203b are each inclined with respect to each of the top surface 201a of the substrate 201 and the reference plane 4a. The second inclined surface 203b is directed to a direction different from the first inclined surface 203a. A distance between the first inclined surface 203a and the second inclined surface 203b in a YZ cross section perpendicular to the top surface 201a of the substrate 201 becomes smaller in the direction away from the top surface 201a of the substrate 201. Both of the top surface 201a of the substrate 201 and the reference plane 4a correspond to the “reference plane” in the disclosure.

In the example embodiment, there are plurality of protruding surfaces 203c, and thus there are a plurality of first inclined surfaces 203a and a plurality of second inclined surfaces 203b. The insulating layer 203 includes the plurality of first inclined surfaces 203a and the plurality of second inclined surfaces 203b.

The plurality of lower electrodes 61A are disposed on the plurality of first inclined surfaces 203a. The plurality of lower electrodes 61B are disposed on the plurality of second inclined surfaces 203b. As described above, the first inclined surface 203a and the second inclined surface 203b are each inclined with respect to the top surface 201a of the substrate 201, i.e., the XY plane. The top surface of each of the plurality of lower electrodes 61A and the top surface of each of the plurality of lower electrode 61B are thus also inclined with respect to the XY plane. The reference plane 4a is parallel to the XY plane. Thus, it can be said that the plurality of first MR elements 50A and the plurality of second MR elements 50B are disposed on the inclined surfaces inclined with respect to the reference plane 4a. The insulating layer 203 is a member for supporting each of the plurality of first MR elements 50A and the plurality of second MR elements 50B so as to allow each of the MR elements to be inclined with respect to the reference plane 4a.

In the example embodiment, the first inclined surface 203a may be a curved surface. The first MR elements 50A are curved along the curved surface (first inclined surface 203a). Even in such a case, the magnetization direction of the magnetization pinned layer of each of the first MR elements 50A is defined as a straight direction for convenience sake. Similarly, in the example embodiment, the second inclined surface 203b may be a curved surface. The second MR elements 50B are curved along the curved surface (second inclined surface 203b). Even in such a case, the magnetization direction of the magnetization pinned layer of each of the second MR elements 50B is defined as a straight direction for convenience sake.

Each of the plurality of first MR elements 50A may have a bottom surface having a shape along the first inclined surface 203a. Each of the plurality of second MR elements 50B may have a bottom surface having a shape along the second inclined surfaces 203b. Now, focus is placed on any one of the plurality of first MR elements 50A and any one of the plurality of second MR elements 50B. The any given first MR element 50A and the any given second MR element 50B are not located on the same inclined surface.

The plurality of first magnetic field generators 70A may be substantially disposed on the plurality of first inclined surfaces 203a, but are not disposed on the plurality of second inclined surfaces 203b. Each of the plurality of first magnetic field generators 70A may have a bottom surface that has a shape along the first inclined surface 203a and has substantially the same shape at least in part as that of the bottom surface of the first MR element 50A.

The plurality of second magnetic field generators 70B may be substantially disposed on the plurality of second inclined surfaces 203b, but are not disposed on the plurality of first inclined surfaces 203a. Each of the plurality of second magnetic field generators 70B may have a bottom surface that has a shape along the second inclined surface 203b and has substantially the same shape at least in part as that of the bottom surface of the second MR element 50B.

Now, focus is placed on any one of the plurality of first magnetic field generators 70A and any one of the plurality of second magnetic field generators 70B. The any given first magnetic field generator 70A and the any given second magnetic field generator 70B are not located on the same inclined surface.

The insulating layer 203 further includes a flat surface 203d present around the plurality of protruding surfaces 203c. The plurality of protruding surfaces 203c protrude from the flat surface 203d in the Z direction. The plurality of protruding surfaces 203c are disposed at specific distances from each other so that the flat surface 203d is formed between two adjacent protruding surfaces 203c.

The insulating layer 203 may have groove portions recessed from the flat surface in the −Z direction. In such a case, the plurality of protruding surfaces 203c may be present in the groove portions.

As shown in FIG. 8, the plurality of first magnetic field generators 70A are disposed so that two or more first magnetic field generators 70A are arranged in each row in the X direction and in each row in the Y direction. Each of the plurality of first MR elements 50A is located between two adjacent first magnetic field generators 70A in the direction parallel to the X direction. Two or more first MR elements 50A and two or more first magnetic field generators 70A may be arranged in a row along the direction parallel to the X direction on one first inclined surface 203a.

In the example shown in FIG. 8, two first magnetic field generators 70A are disposed between the two adjacent first MR elements 50A in the direction parallel to the X direction. Note that the number of the first magnetic field generators 70A disposed between the two first MR elements 50A is not limited to two, but may be one.

Similarly, the plurality of second magnetic field generators 70B are disposed so that two or more second magnetic field generators 70B are arranged in each row in the X direction and in each row in the Y direction. Each of the plurality of second MR elements 50B is located between two adjacent second magnetic field generators 70B in the direction parallel to the X direction. Two or more second MR elements 50B and two or more second magnetic field generators 70B may be arranged in a row along the direction parallel to the X direction on one second inclined surface 203b.

In the example shown in FIG. 8, two second magnetic field generators 70B are disposed between the two adjacent second MR elements 50B in the direction parallel to the X direction. Note that the number of the second magnetic field generators 70B disposed between the two second MR elements 50B is not limited to two, but may be one.

The rows of the two or more first MR elements 50A and the two or more first magnetic field generators 70A and the rows of the two or more second MR elements 50B and the two or more second magnetic field generators 70B are alternately arranged in the direction parallel to the Y direction.

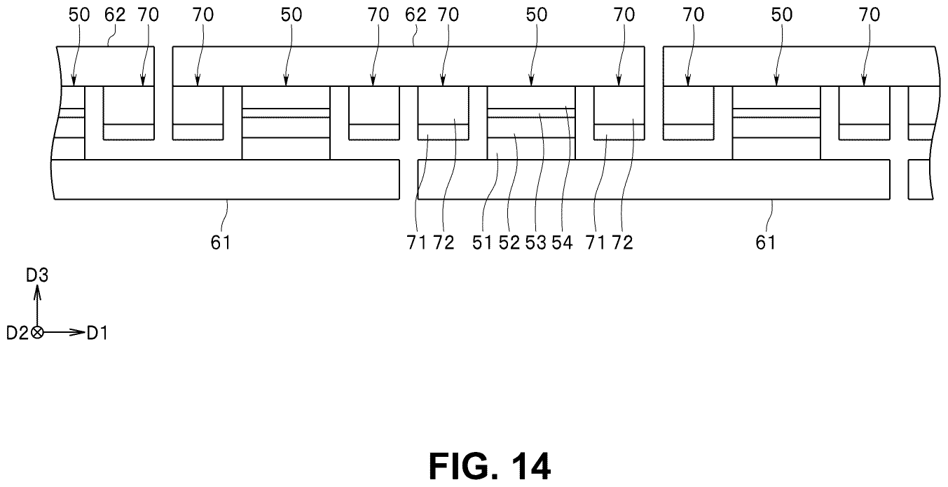

The plurality of first MR elements 50A are connected in series by the plurality of lower electrodes 61A and the plurality of upper electrodes 62A. A method for connecting the plurality of first MR elements 50A will now be described in detail with reference to FIG. 14. In FIG. 14, the reference numerals 61 denote lower electrodes each corresponding to any given MR element 50, and the reference numerals 62 denote upper electrodes each corresponding to any given MR element 50. In FIG. 14, the reference numerals 70 denote any given magnetic field generators.

As shown in FIG. 14, each lower electrode 61 has a long slender shape. Two adjacent lower electrodes 61 in the longitudinal direction of the lower electrodes 61 have a gap formed therebetween. The MR elements 50 are disposed near both ends in the longitudinal direction on the top surface of each lower electrode 61. Each upper electrode 62 has a long slender shape, and electrically connects two adjacent MR elements 50 that are disposed on two adjacent lower electrodes 61 in the longitudinal direction of the lower electrodes 61.

Two magnetic field generators 70 are located between two adjacent MR elements 50 in the longitudinal direction of the lower electrodes 61. Gaps are formed between the magnetic field generator 70 and the MR element 50, and between the magnetic field generator 70 and the lower electrodes 61. Note that the magnetic field generator 70 may or may not be in contact with the upper electrodes 62.

Although not shown, an MR element 50 located at the end of a row of two or more MR elements 50 is connected to another MR element 50 located at the end of another row of two or more MR elements 50 adjacent in a direction intersecting the longitudinal direction of the lower electrodes 61. Such two MR elements 50 are connected to each other by a not-shown electrode. The not-shown electrode may be an electrode connecting the bottom surfaces or the top surfaces of the two MR elements 50.

If the MR elements 50 in FIG. 14 are the first MR elements 50A, the lower electrodes 61, the upper electrodes 62, and the magnetic field generators 70 in FIG. 14 correspond to the lower electrodes 61A, the upper electrodes 62A, and the first magnetic field generators 70A, respectively. If the MR elements 50 in FIG. 14 are the second MR elements 50B, the lower electrodes 61, the upper electrodes 62, and the magnetic field generators 70 in FIG. 14 correspond to the lower electrodes 61B, the upper electrodes 62B, and the second magnetic field generators 70B, respectively.

Now, the definitions of a first direction D1, a second direction D2, and a third direction D3 shown in FIG. 14 will be described. The first direction D1, the second direction D2, and the third direction D3 are orthogonal to one another. The first direction D1 is a direction parallel to the longitudinal direction of the lower electrodes 61 (the same as the longitudinal direction of the upper electrodes 62). The third direction D3 is a direction from the lower electrodes 61 to the upper electrodes 62.

If the MR elements 50 shown in FIG. 14 are the first MR elements 50A, the first direction D1 is the X direction or the −X direction. The second direction D2 is the U direction or the −U direction. The third direction D3 is a direction intersecting the first inclined surfaces 203a. If the MR elements 50 shown in FIG. 14 are the second MR elements 50B, the first direction D1 is the X direction or the −X direction. The second direction D2 is the V direction or the −V direction. The third direction D3 is a direction intersecting the second inclined surfaces 203b.

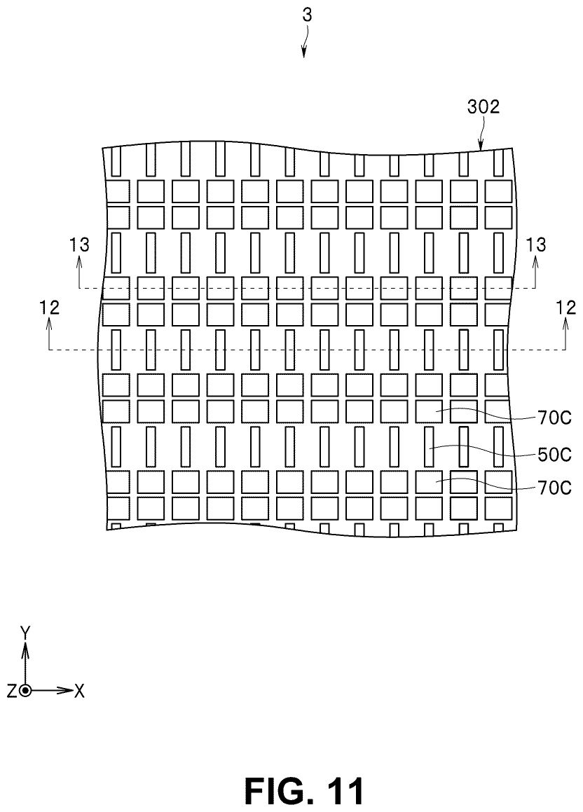

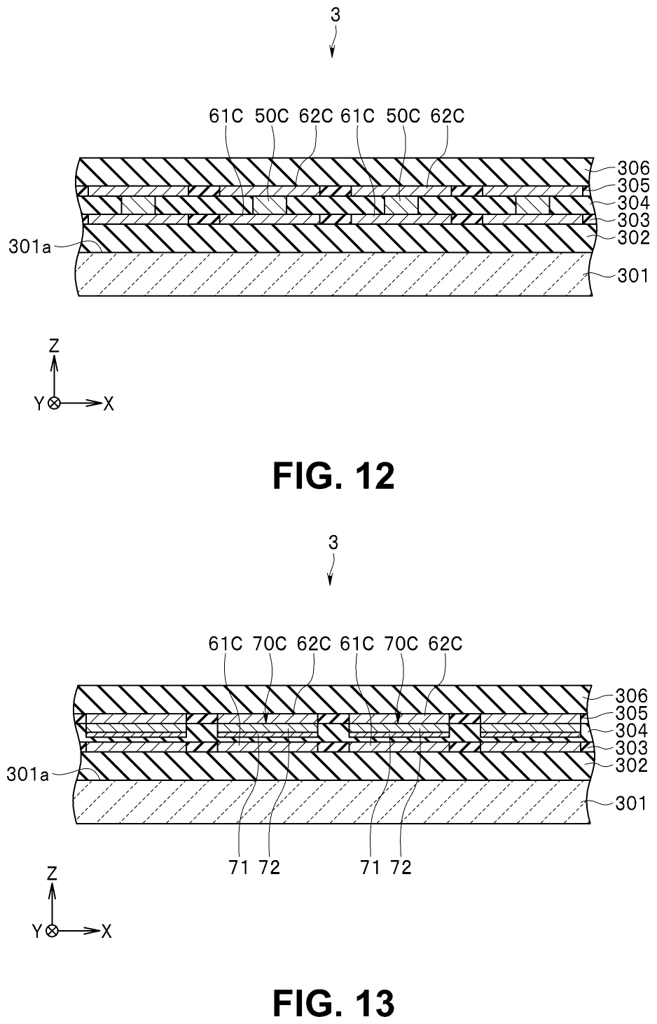

Next, a structure of the second chip 3 will be described in detail with reference to FIGS. 11 to 13. FIG. 11 is a plan view showing a part of the second chip 3. FIGS. 12 and 13 are sectional views each showing a part of the second chip 3. FIG. 12 shows a part of a cross section at the position indicated by the line 12-12 in FIG. 11. FIG. 13 shows a part of a cross section at the position indicated by the line 13-13 in FIG. 11.

The second chip 3 includes a substrate 301 having a top surface 301a, insulating layers 302, 303, 304, 305, and 306, a plurality of lower electrodes 61C, a plurality of upper electrodes 62C, and a plurality of third magnetic field generators 70C. The top surface 301a of the substrate 301 is parallel to the XY plane. The Z direction is a direction perpendicular to the top surface 301a of the substrate 301.

The insulating layer 302 is disposed on the substrate 301. The plurality of lower electrodes 61C are disposed on the insulating layer 302. The insulating layer 303 is disposed around the plurality of lower electrodes 61C on the insulating layer 302. The plurality of third MR elements 50C are disposed on the plurality of lower electrodes 61C. The insulating layer 304 is disposed, on the plurality of lower electrodes 61C and the insulating layer 303, around the plurality of third MR elements 50C. The plurality of upper electrodes 62C are disposed on the plurality of third MR elements 50C and the insulating layer 304. The insulating layer 305 is disposed around the plurality of upper electrodes 62C on the insulating layer 304. The insulating layer 306 is disposed on the plurality of upper electrodes 62C and the insulating layer 305.

The plurality of third magnetic field generators 70C are embedded in the insulating layer 304. Each of the plurality of third magnetic field generators 70C is located at distances from the third MR elements 50C and the lower electrodes 61C. The second chip 3 may include insulating films interposed respectively between each of the plurality of third magnetic field generators 70C and each of the plurality of third MR elements 50C and between each of the plurality of third magnetic field generators 70C and each of the plurality of lower electrodes 61C. The top surface of each of the plurality of third magnetic field generators 70C may be in contact with the bottom surfaces of the upper electrodes 62C.

The second chip 3 may include a support member that supports the plurality of third MR elements 50C. In particular, in the example embodiment, the support member includes the insulating layer 302. The top surface of the insulating layer 302 may include a flat surface.

The top surface 301a of the substrate 301 is parallel to the XY plane, and the top surface of each of the plurality of lower electrodes 61C is also parallel to the XY plane. Moreover, the reference plane 4a is parallel to the XY plane. The plurality of third MR elements 50C can thus be said to be disposed on a plane parallel to the reference plane 4a.

As shown in FIG. 11, the plurality of third magnetic field generators 70C are disposed so that two or more third magnetic field generators 70C are arranged both in the X and Y directions. Each of the plurality of third MR elements 50C is located between two adjacent third magnetic field generators 70C in the direction parallel to the Y direction.

In the example shown in FIG. 11, two third magnetic field generators 70C are disposed between two adjacent third MR elements 50C in the direction parallel to the Y direction. Note that the number of the third magnetic field generators 70C disposed between the two third MR elements 50C is not limited to two, but may be one.

The plurality of third MR elements 50C are connected in series by the plurality of lower electrodes 61C and the plurality of upper electrodes 62C. The foregoing description of the method for connecting the plurality of first MR elements 50A also applies to a method for connecting the plurality of third MR elements 50C. If the MR elements 50 in FIG. 14 are the third MR elements 50C, the lower electrodes 61, the upper electrodes 62, and the magnetic field generators 70 in FIG. 14 correspond to the lower electrodes 61C, the upper electrodes 62C, and the third magnetic field generators 70C, respectively.

If the MR elements 50 shown in FIG. 14 are the third MR elements 50C, the first direction D1 is the Y direction or the −Y direction. The second direction D2 is the X direction or the −X direction. The third direction D3 is the Z direction.

Next, the MR elements 50 will be described in more detail with reference to FIG. 14. In FIG. 14, the reference numeral 52 denotes the magnetization pinned layer, the reference numeral 53 denotes the gap layer, and the reference numeral 54 denotes the free layer. The MR element 50 further includes an antiferromagnetic layer 51. The antiferromagnetic layer 51, the magnetization pinned layer 52, the gap layer 53, and the free layer 54 are stacked in this order from the lower electrode 61 to the upper electrode 62. The antiferromagnetic layer 51 is formed of an antiferromagnetic material, and is exchange-coupled with the magnetization pinned layer 52 to thereby fix the magnetization direction of the magnetization pinned layer 52. Note that the magnetization pinned layer 52 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled. In a case where the magnetization pinned layer 52 is the self-pinned layer, the antiferromagnetic layer 51 may be omitted.

Note that the layers 51 to 54 of each MR element 50 may be stacked in the reverse order to that shown in FIG. 14.

In the first MR element 50A, the antiferromagnetic layer 51, the magnetization pinned layer 52, the gap layer 53, and the free layer 54 are stacked in a direction intersecting the first inclined surface 203a (see FIGS. 8 and 9). This direction may be a direction perpendicular to the first inclined surface 203a.

In the second MR element 50B, the antiferromagnetic layer 51, the magnetization pinned layer 52, the gap layer 53, and the free layer 54 are stacked in a direction intersecting the second inclined surface 203b (see FIGS. 8 and 9). This direction may be a direction perpendicular to the second inclined surface 203b.

In the third MR element 50C, the antiferromagnetic layer 51, the magnetization pinned layer 52, the gap layer 53, and the free layer 54 are stacked in a direction intersecting the top surface of the insulating layer 302 (see FIGS. 12 and 13). This direction may be a direction perpendicular to the top surface of the insulating layer 302, i.e., the Z direction.

Next, the magnetic field generators 70 will be described in more detail with reference to FIGS. 10, 13, and 14. Each magnetic field generator 70 includes the ferromagnetic portion 72 and the antiferromagnetic portion 71 that is in contact with the ferromagnetic portion 72 and is exchange-coupled with the ferromagnetic portion 72.

The ferromagnetic portion 72 may have its overall magnetization. The overall magnetization of the ferromagnetic portion 72 refers to the volume average of the vector sum of magnetic moments in units of atoms, crystal lattices, or the like in the entire ferromagnetic portion 72. Hereinafter, the overall magnetization of the ferromagnetic portion 72 will simply be referred to as the magnetization of the ferromagnetic portion 72.

In the magnetic field generator 70, the antiferromagnetic portion 71 and the ferromagnetic portion 72 are exchange-coupled with each other to thereby define the magnetization direction of the ferromagnetic portion 72. The ferromagnetic portion 72 and the antiferromagnetic portion 71 generate a magnetic field to be applied to the MR elements 50 based on the magnetization of the ferromagnetic portion 72. The magnetic field generator 70 configured in this way has high resistance to disturbance magnetic fields.

The ferromagnetic portion 72 is formed of a ferromagnetic material containing one or more elements selected from Co, Fe, and Ni. Examples of such a ferromagnetic material include CoFe, CoFeB, and CoNiFe. The antiferromagnetic portion 71 is formed of an antiferromagnetic material such as IrMn and PtMn.

The dimension of the magnetic field generator 70 in a direction parallel to the second direction D2 is greater than the dimension of the MR element 50 in the direction parallel to the second direction D2. The dimension of the magnetic field generator 70 in the direction parallel to the second direction D2 is greater than the dimension of the magnetic field generator 70 in the direction parallel to the first direction D1.

When seen in the first direction D1, at least a part of the free layer 54 of the MR element 50 may overlap with at least a part of the ferromagnetic portion 72 of the magnetic field generator 70. In the example shown in FIG. 14, the entire free layer 54 overlaps with a part of the ferromagnetic portion 72 when seen in the first direction D1.

In the first magnetic field generator 70A, the antiferromagnetic portion 71 and the ferromagnetic portion 72 are stacked in a direction intersecting the first inclined surface 203a (see FIG. 10). This direction may be a direction perpendicular to the first inclined surface 203a. The antiferromagnetic portion 71 and the ferromagnetic portion 72 may each have a bottom surface facing the first inclined surface 203a and inclined with respect to the top surface 201a of the substrate 201, i.e., the XY plane. Such a bottom surface can be implemented by forming the antiferromagnetic portion 71 in such a thickness that the shape of the first inclined surface 203a appears. The thickness of the ferromagnetic portion 72 of the first magnetic field generator 70A in a direction perpendicular to the first inclined surface 203a may be smaller than the thickness of the first MR element 50A in the direction perpendicular to the first inclined surface 203a. Furthermore, the thickness of the ferromagnetic portion 72 of the first magnetic field generator 70A in the direction perpendicular to the first inclined surface 203a may be larger than the thickness of the free layer 54 of the first MR element 50A in the direction perpendicular to the first inclined surface 203a.

In the second magnetic field generator 70B, the antiferromagnetic portion 71 and the ferromagnetic portion 72 are stacked in a direction intersecting the second inclined surface 203b (see FIG. 10). This direction may be a direction perpendicular to the second inclined surface 203b. The antiferromagnetic portion 71 and the ferromagnetic portion 72 may each have a bottom surface facing the second inclined surface 203b and inclined with respect to the top surface 201a of the substrate 201, i.e., the XY plane. Such a bottom surface can be implemented by forming the antiferromagnetic portion 71 in such a thickness that the shape of the second inclined surface 203b appears. The thickness of the ferromagnetic portion 72 of the second magnetic field generator 70B in a direction perpendicular to the second inclined surface 203b may be smaller than the thickness of the second MR element 50B in the direction perpendicular to the second inclined surface 203b. Furthermore, the thickness of the ferromagnetic portion 72 of the second magnetic field generator 70B in the direction perpendicular to the second inclined surface 203b may be larger than the thickness of the free layer 54 of the second MR element 50B in the direction perpendicular to the second inclined surface 203b.

In the third magnetic field generator 70C, the antiferromagnetic portion 71 and the ferromagnetic portion 72 are stacked in a direction intersecting the top surface of the insulating layer 302 (see FIG. 13). This direction may be a direction perpendicular to the top surface of the insulating layer 302, i.e., the Z direction.

The magnetic field generator 70 may further include a not-shown buffer layer and a not-shown cap layer. The buffer layer, the antiferromagnetic portion 71, the ferromagnetic portion 72, and the cap layer are stacked in this order. Each of the buffer layer and the cap layer are formed of a nonmagnetic metallic material such as Ru, Ta, Cu, and Cr, for example.

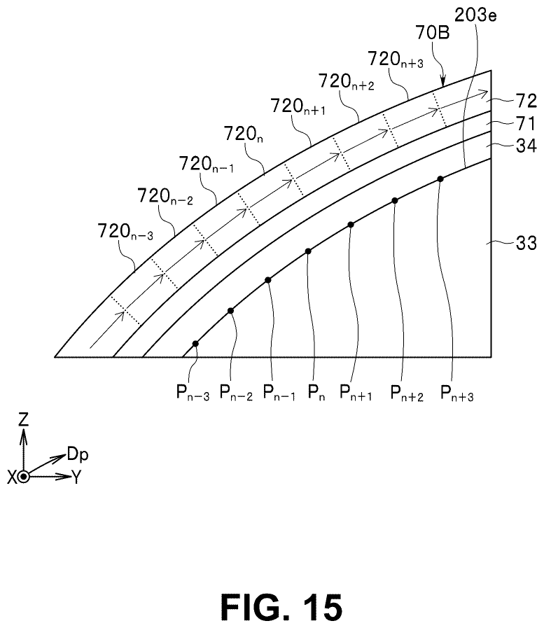

Next, the shapes of the first and second inclined surfaces 203a and 203b will be described in detail with reference to FIG. 15. FIG. 15 shows a cross section that is parallel to the YZ plane and perpendicular to the top surface 201a of the substrate 201 and intersects the second magnetic field generator 70B. Hereinafter, even in such a case where description will be made with reference to FIG. 15, features common to the first magnetic field generator 70A and the second magnetic field generator 70B will be described as features of any given magnetic field generator 70, and features common to the first inclined surface 203a and the second inclined surface 203b will be described as features of any given inclined surface 203e.

Here, as shown in FIG. 15, a direction Dp parallel to the YZ plane is defined. The direction Dp is a direction along the first inclined surface 203a or the second inclined surface 203b and away from the top surface 201a of the substrate 201. As shown in FIG. 15, when the direction Dp is defined as a direction along the second inclined surface 203b, the direction Dp is a direction between the Y direction and the Z direction. Although not shown, when the direction Dp is defined as a direction along the first inclined surface 203a, the direction Dp is a direction between the −Y direction and the Z direction.

Furthermore, in the following description, the direction along the first inclined surface 203a or the second inclined surface 203b and parallel to the direction Dp will simply be referred to as a direction along the inclined surface. This direction is also a direction along the inclined surface and in which the distance from the top surface 201a of the substrate 201 changes.

In FIG. 15, a plurality of points denoted by the reference numerals Pₙ₋₃, Pₙ₋₂, Pₙ₋₁, Pₙ, Pₙ₊₁, Pₙ₊₂, and Pₙ₊₃ are any given points on the inclined surface 203e, and indicate points at positions different from each other in a direction (Z direction) perpendicular to the top surface 201a of the substrate 201. Hereinafter, any given point of the points Pₙ₋₃ to Pₙ₊₃ is represented by the reference numeral P. An angle that the inclined surface 203e forms with respect to the top surface 201a of the substrate 201 at the any given point P changes depending on the position of the any given point P in the direction (Z direction) perpendicular to the top surface 201a of the substrate 201. For example, the point Pₙ₊₁ is located further away from the top surface 201a of the substrate 201 than the point Pₙ. The angle that the inclined surface 203e forms with respect to the top surface 201a of the substrate 201 at the point Pₙ₊₁ is smaller than the angle that the inclined surface 203e forms with respect to the top surface 201a of the substrate 201 at the point Pₙ. Furthermore, the point Pₙ₋₁ is located closer to the top surface 201a of the substrate 201 than the point Pₙ. The angle that the inclined surface 203e forms with respect to the top surface 201a of the substrate 201 at the point Pₙ₋₁ is greater than the angle that the inclined surface 203e forms with respect to the top surface 201a of the substrate 201 at the point Pₙ.

Next, the relationship between the shape of the inclined surface 203e and the ferromagnetic portion 72 of the magnetic field generator 70 will be described with reference to FIG. 15. In FIG. 15, the reference numerals 720ₙ₋₃, 720ₙ₋₂, 720ₙ₋₁, 720ₙ, 720ₙ₊₁, 720ₙ₊₂, and 720ₙ₊₃ each indicate a part of the ferromagnetic portion 72. In FIG. 15, the boundary between two adjacent ones of the parts 720ₙ₋₃ to 720ₙ₊₃ is indicated by a dotted line. Hereinafter, any given one of the parts 720ₙ₋₃ to 720ₙ₊₃ is represented by the reference numeral 720. The part 720 is located at a position corresponding to the point P on the inclined surface. For example, the part 720ₙ is located forward of the point Pₙ in a direction perpendicular to the inclined surface 203e. The other parts 720ₙ₋₃ to 720ₙ₋₁ and 720ₙ₊₁ to 720ₙ₊₃ are also located similarly to the part 720ₙ.

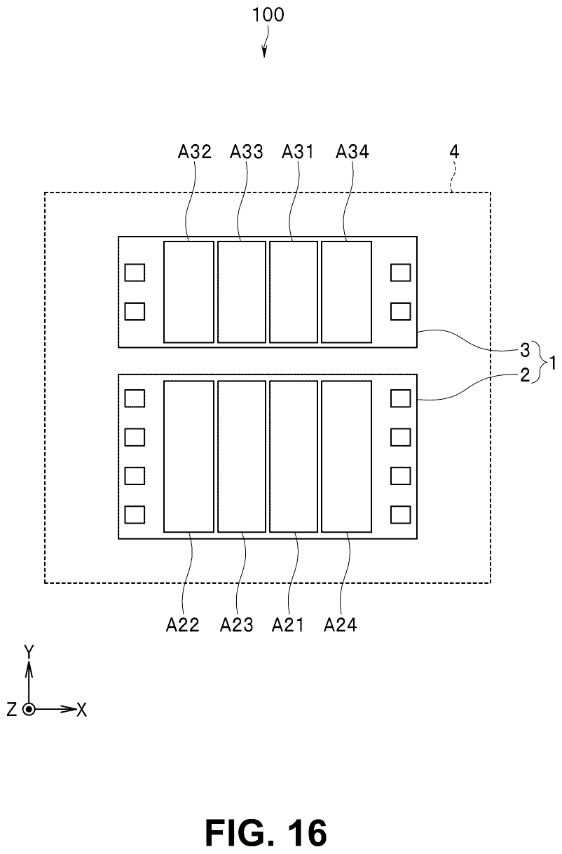

Next, the layout of the plurality of MR elements 50 and the plurality of magnetic field generators 70 will be described. A first example of the layout of the plurality of MR elements 50 and the plurality of magnetic field generators 70 will initially be described with reference to FIG. 16. The first chip 2 includes a first element layout area for arranging the plurality of first MR elements 50A, the plurality of second MR elements 50B, the plurality of first magnetic field generators 70A, and the plurality of second magnetic field generators 70B. Since the first chip 2 is a component of the magnetic sensor 1, the magnetic sensor 1 can be said to include the first element layout area. In the example embodiment, the first element layout area, and a second element layout area and a plurality of areas that are to be described below are defined as planar areas parallel to the XY plane. When seen in the Z direction, the plurality of first MR elements 50A, the plurality of second MR elements 50B, the plurality of first magnetic field generators 70A, and the plurality of second magnetic field generators 70B overlap with the first element layout area. In the example embodiment, it is assumed for convenience sake that the first element layout area is present on the top surface of the insulating layer 203.

The first element layout area includes a first area A21, a second area A22, a third area A23, and a fourth area A24. The first area A21 is an area corresponding to the first resistor sections R11 and R21. The second area A22 is an area corresponding to the second resistor sections R12 and R22. The third area A23 is an area corresponding to the third resistor sections R13 and R23. The fourth area A24 is an area corresponding to the fourth resistor sections R14 and R24.

The plurality of first MR elements 50A are disposed dividedly in the first to fourth areas A21 to A24. The first MR elements 50A constituting the first resistor section R11 may be disposed in the first area A21. The first MR elements 50A constituting the second resistor section R12 may be disposed in the second area A22. The first MR elements 50A constituting the third resistor section R13 may be disposed in the third area A23. The first MR elements 50A constituting the fourth resistor section R14 may be disposed in the fourth area A24.

The plurality of first magnetic field generators 70A may be disposed dividedly in the first to fourth areas A21 to A24. Each of a plurality of first magnetic field generators 70A disposed in two of the first to fourth areas A21 to A24 and each of a plurality of first magnetic field generators 70A disposed in the other two of the first to fourth areas A21 to A24 have magnetization in respective different directions.

Here, the direction of the arrows denoted by the reference numeral M11 shown in FIG. 5 will be referred to as the direction M11. The directions of the arrows denoted by reference numerals other than the reference numeral M11 will be referred to in a manner similar to the direction M11. The magnetization of the ferromagnetic portion 72 of each of the plurality of first magnetic field generators 70A disposed in the first area A21 includes a component in the direction M11. The magnetization of the ferromagnetic portion 72 of each of the plurality of first magnetic field generators 70A disposed in the second area A22 includes a component in the direction M12 (see FIG. 5). The magnetization of the ferromagnetic portion 72 of each of the plurality of first magnetic field generators 70A disposed in the third area A23 includes a component in the direction M13 (see FIG. 5). The magnetization of the ferromagnetic portion 72 of each of the plurality of first magnetic field generators 70A disposed in the fourth area A24 includes a component in the direction M14 (see FIG. 5).

As shown in FIG. 5, the directions M11 and M12 are the same direction as the X direction. The magnetization of the ferromagnetic portion 72 of each of the plurality of first magnetic field generators 70A disposed in the first area A21 and the plurality of first magnetic field generators 70A disposed in the second area A22 thus may include a component in the X direction. This magnetization may include the component in the X direction as a main component. In such a case, the magnetization direction is the X direction or substantially the X direction.

As shown in FIG. 5, the directions M13 and M14 are the same direction as the −X direction. The magnetization of the ferromagnetic portion 72 of each of the plurality of first magnetic field generators 70A disposed in the third area A23 and the plurality of first magnetic field generators 70A disposed in the fourth area A24 thus may include a component in the −X direction. This magnetization may include the component in the −X direction as a main component. In such a case, the magnetization direction is the −X direction or substantially the −X direction.

The foregoing description of the layout of the plurality of first MR elements 50A and the layout and the magnetization directions of the plurality of first magnetic field generators 70A also applies to the plurality of second MR elements 50B and the plurality of second magnetic field generators 70B. A description of the layout of the plurality of second MR elements 50B is given by replacing the first MR elements 50A, the first resistor sections R11, the second resistor sections R12, the third resistor sections R13, and the fourth resistor sections R14 in the foregoing description of the layout of the plurality of first MR elements 50A with the second MR elements 50B, the first resistor sections R21, the second resistor sections R22, the third resistor sections R23, and the fourth resistor sections R24, respectively. A description of the layout and the magnetization directions of the plurality of second magnetic field generators 70B is given by replacing the first magnetic field generators 70A and the directions M11, M12, M13, and M14 in the foregoing description of the layout and the magnetization directions of the plurality of first magnetic field generators 70A with the second magnetic field generators 70B and the directions M21, M22, M23, and M24 (see FIG. 6), respectively.

In the first example, the first to fourth areas A21 to A24 are arranged in the order of the areas A22, A23, A21, and A24 from the edge of the first chip 2 on the side of the −X direction to the edge of the first chip 2 on the side of the X direction. The plurality of first MR elements 50A, the plurality of second MR elements 50B, the plurality of first magnetic field generators 70A, and the plurality of second magnetic field generators 70B are each arranged by the same rule as with the first to fourth areas A21 to A24 depending on the foregoing features.

The second chip 3 includes a second element layout area for arranging the plurality of third MR elements 50C and the plurality of third magnetic field generators 70C. Since the second chip 3 is a component of the magnetic sensor 1, the magnetic sensor 1 can be said to include the second element layout area. When seen in the Z direction, the plurality of third MR elements 50C and the plurality of third magnetic field generators 70C overlap with the second element layout area. In the example embodiment, it is assumed for convenience sake that the second element layout area is present on the top surface of the insulating layer 302.

The second element layout area includes a first area A31, a second area A32, a third area A33, and a fourth area A34. The first area A31 is an area corresponding to the first resistor section R31. The second area A32 is an area corresponding to the second resistor section R32. The third area A33 is an area corresponding to the third resistor section R33. The fourth area A34 is an area corresponding to the fourth resistor section R34.

The plurality of third MR elements 50C are disposed dividedly in the first to fourth areas A31 to A34. The third MR elements 50C constituting the first resistor section R31 are disposed in the first area A31. The third MR elements 50C constituting the second resistor section R32 are disposed in the second area A32. The third MR elements 50C constituting the third resistor section R33 are disposed in the third area A33. The third MR elements 50C constituting the fourth resistor section R34 are disposed in the fourth area A34.

The plurality of third magnetic field generators 70C are disposed dividedly in the first to fourth areas A31 to A34. Each of a plurality of third magnetic field generators 70C disposed in two of the first to fourth areas A31 to A34 and each of a plurality of third magnetic field generators 70C disposed in the other two of the first to fourth areas A31 to A34 have magnetization in respective different directions.

The magnetization of the ferromagnetic portion 72 of each of the plurality of third magnetic field generators 70C disposed in the first area A31 includes a component in the direction M31 (see FIG. 7). The magnetization of the ferromagnetic portion 72 of each of the plurality of third magnetic field generators 70C disposed in the second area A32 includes a component in the direction M32 (see FIG. 7). The magnetization of the ferromagnetic portion 72 of each of the plurality of third magnetic field generators 70C disposed in the third area A33 includes a component in the direction M33 (see FIG. 7). The magnetization of the ferromagnetic portion 72 of each of the plurality of third magnetic field generators 70C disposed in the fourth area A34 includes a component in the direction M34 (see FIG. 7).

As shown in FIG. 7, the directions M31 and M32 are the same direction as the Y direction. The magnetization of the ferromagnetic portion 72 of each of the plurality of third magnetic field generators 70C disposed in the first area A31 and the plurality of third magnetic field generators 70C disposed in the second area A32 thus includes a component in the Y direction. This magnetization may include the component in the Y direction as a main component. In such a case, the magnetization direction is the Y direction or substantially the Y direction.

As shown in FIG. 7, the directions M33 and M34 are the same direction as the −Y direction. The magnetization of the ferromagnetic portion 72 of each of the plurality of third magnetic field generators 70C disposed in the third area A33 and the plurality of third magnetic field generators 70C disposed in the fourth area A34 thus includes a component in the −Y direction. This magnetization may include the component in the −Y direction as a main component. In such a case, the magnetization direction is the −Y direction or substantially the −Y direction.

In the first example, the first to fourth areas A31 to A34 are arranged in the order of the areas A32, A33, A31, and A34 from the edge of the second chip 3 on the side of the −X direction to the edge of the second chip 3 on the side of the X direction. The plurality of third MR elements 50C and the plurality of third magnetic field generators 70C are each arranged by the same rule as with the first to fourth areas A31 to A34 depending on the foregoing features.

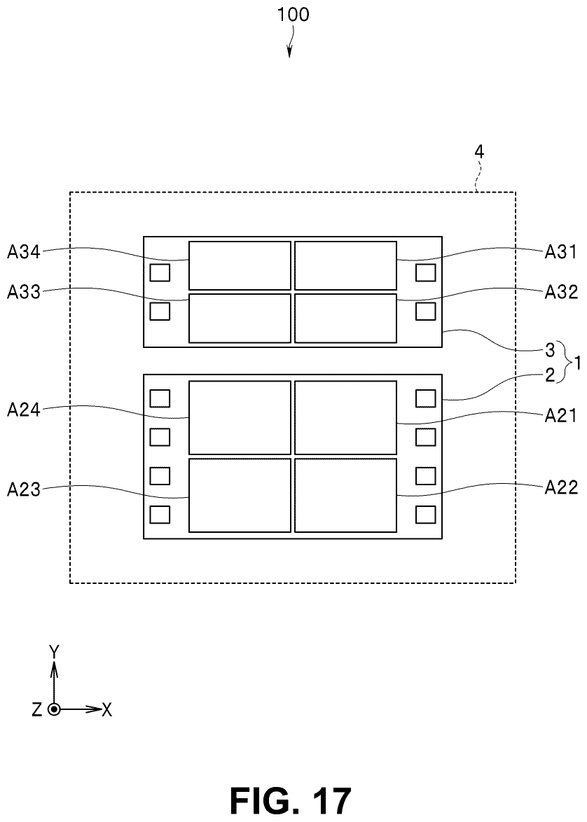

Next, a second example of the layout of the plurality of MR elements 50 and the plurality of magnetic field generators 70 will be described with reference to FIG. 17. In the second example, the first and second areas A21 and A22 are arranged in this order in the −Y direction. The third and fourth areas A23 and A24 are located forward of the second and first areas A22 and A21 in the −X direction, respectively.

In the second example, the first and second areas A31 and A32 are arranged in this order in the −Y direction. The third and fourth areas A33 and A34 are located forward of the second and first areas A32 and A31 in the −X direction, respectively.

Next, a manufacturing method for the magnetic sensor device 100 of the example embodiment will be briefly described. The manufacturing method for the magnetic sensor device 100 includes a step of forming the first chip 2, a step of forming the second chip 3, and a step of mounting the first and second chips 2 and 3 on the support 4.

The step of forming the first chip 2 and the step of forming the second chip 3 each include a step of forming a plurality of MR elements 50 and a step of forming a plurality of magnetic field generators 70.

In the step of forming the plurality of MR elements 50, a plurality of initial MR elements to later become the plurality of MR elements 50 are initially formed. Each of the plurality of initial MR elements includes an initial magnetization pinned layer to later become the magnetization pinned layer 52, the free layer 54, the gap layer 53, and the antiferromagnetic layer 51.

Next, the magnetization directions of the initial magnetization pinned layers are fixed using laser light and external magnetic fields including the components in specific directions. For example, a plurality of initial MR elements to later become the plurality of first MR elements 50A constituting the first and third resistor sections R11 and R13 of the first detection circuit 10 are irradiated with laser light while an external magnetic field in the Y direction is applied thereto. The irradiation of the laser light is performed so that the temperature of the plurality of initial MR elements irradiated with the laser light becomes equal to or higher than a blocking temperature of the antiferromagnetic layer 51. The temperature of the plurality of initial MR elements can be adjusted, for example, by the intensity and pulse width of the laser light.

The external magnetic field in the Y direction can be divided into a component in the U direction and a component in a direction orthogonal to the U direction. After the irradiation with the laser light, when the temperature of the plurality of initial MR elements becomes lower than the blocking temperature, the magnetization directions of the initial magnetization pinned layers are fixed to the U direction. This makes the initial magnetization pinned layers into the magnetization pinned layers 52, and the initial MR elements into the first MR elements 50A.

In the plurality of initial MR elements to later become the plurality of first MR elements 50A constituting the second and fourth resistor sections R12 and R14 of the first detection circuit 10, the magnetization direction of the initial magnetization pinned layer of each of the plurality of initial MR elements can be fixed to the −U direction by using an external magnetic field in the −Y direction. The plurality of first MR elements 50A are thereby formed. The plurality of second MR elements 50B and the plurality of third MR elements 50C are also formed using a method similar to that used to form the plurality of first MR elements 50A.

The MR element 50 is completed by patterning a stacked film by etching so that side surfaces of the MR element 50 are formed on the stacked film after fixing the magnetization direction of the magnetization pinned layer 52. Note that the step of fixing the magnetization direction of the initial magnetization pinned layer may be performed after forming the side surfaces of the MR element 50 on the stacked film.

In the step of forming the plurality of magnetic field generators 70, a plurality of initial magnetic field generators to later become the plurality of magnetic field generators 70 are initially formed. Each of the plurality of initial magnetic field generators includes an initial ferromagnetic portion to later become a ferromagnetic portion 72, and an antiferromagnetic portion 71.

Next, the magnetization directions of the initial ferromagnetic portions are fixed to a specific direction using laser light and an external magnetic field including a component in the foregoing specific direction. For example, the plurality of initial magnetic field generators to become the plurality of first magnetic field generators 70A and the plurality of second magnetic field generators 70B disposed in the first and second areas A21 and A22 of the first chip 2 are irradiated with the laser light while an external magnetic field in the X direction is applied thereto. The irradiation of the laser light is performed so that the temperature of the plurality of initial magnetic field generators irradiated with the laser light becomes equal to or higher than the blocking temperature of the antiferromagnetic portion 71. The temperature of the plurality of initial magnetic field generators can be adjusted, for example, by the intensity and pulse width of the laser light. After the irradiation with the laser light, when the temperature of the plurality of initial magnetic field generators becomes lower than the blocking temperature, the magnetization directions of the initial ferromagnetic portions are fixed to the X direction. This makes the initial ferromagnetic portions into the ferromagnetic portions 72 and the initial magnetic field generators into the first magnetic field generators 70A or the second magnetic field generators 70B. In addition, in the plurality of initial magnetic field generators to become the plurality of first magnetic field generators 70A and the plurality of second magnetic field generators 70B disposed in the third and fourth areas A23 and A24 of the first chip 2, the magnetization directions of the initial ferromagnetic portions of the plurality of initial magnetic field generators can be fixed to the −X direction by using an external magnetic field in the −X direction. Thus, the plurality of first magnetic field generators 70A and the plurality of second magnetic field generators 70B are formed. The plurality of third magnetic field generators 70C are also formed using a method similar to that used to form the plurality of first magnetic field generators 70A and the plurality of second magnetic field generators 70B.

As can be seen from the foregoing description of the manufacturing method for the magnetic sensor device 100, in the example embodiment, the magnetization directions of the magnetization pinned layers 52 of the first MR elements 50A, the magnetization directions of the magnetization pinned layers 52 of the second MR elements 50B, and the magnetization directions of the magnetization pinned layers 52 of the third MR elements 50C are each fixed by using laser light and an external magnetic field. Moreover, in the example embodiment, the magnetization directions of the ferromagnetic portions 72 of the first magnetic field generators 70A, the magnetization directions of the ferromagnetic portions 72 of the second magnetic field generators 70B, and the magnetization directions of the ferromagnetic portions 72 of the third magnetic field generators 70C are each fixed by using laser light and an external magnetic field.

Here, the intensity of the laser light used to fix the magnetization directions of the ferromagnetic portions 72 will be referred to as the intensity of the laser light for the ferromagnetic portions 72. The intensity of the laser light for the ferromagnetic portions 72 may be lower than the intensity of the laser light used to fix the magnetization directions of the magnetization pinned layers 52. The laser light for the ferromagnetic portions 72 may have the intensity to reduce a change in a magnetoresistive change ratio (hereinafter, referred to as an MR ratio) that is the ratio of a magnetoresistive change to the resistance of the MR element 50. For example, the laser light for the ferromagnetic portions 72 may have the intensity to reduce a change in the MR ratio within 10%, preferably within 5% or within 3%.

Note that the MR ratio may increase or decrease with the irradiation with the laser light for the ferromagnetic portions 72.

Next, the operation and effects of the magnetic sensor 1 according to the example embodiment will be described. In the example embodiment, as described above, the angle that the inclined surface 203e forms with respect to the top surface 201a of the substrate 201 at any given point P changes depending on the position of the any given point P in the direction (Z direction) perpendicular to the top surface 201a of the substrate 201. Therefore, according to the example embodiment, the strength of the magnetic field applied to the MR element 50 by the magnetic field generator 70 can be increased. Hereinafter, the effects will be described in detail with reference to FIG. 15.

In FIG. 15, the arrows drawn to overlap with the parts 720 of the ferromagnetic portion 72 of the magnetic field generator 70 schematically represent magnetic moments in the parts 720. When the magnetic moments in the plurality of parts 720 are directed to a direction parallel to the YZ plane and along the inclined surface, as shown in FIG. 15, the direction of the magnetic moment in each of the plurality of parts 720 coincides or substantially coincides with a tangential direction of the inclined surface 203e at the point P corresponding to the part 720. The magnetic moment in one of two adjacent parts 720 and the magnetic moment in the other of the two adjacent parts 720 thus are directed to directions different from each other. In this case, an exchange interaction acts between the two magnetic moments to align the directions of the magnetic moments.

On the other hand, if the magnetic moments in the plurality of parts 720 are directed to the longitudinal direction of the inclined surface 203e (direction parallel to the X direction), the direction of the magnetic moment in each of the plurality of parts 720 coincides or substantially coincides with each other. In this case, the energy of the exchange interaction thus decreases compared to when the magnetic moments in the plurality of parts 720 are directed to the direction parallel to the YZ plane and along the inclined surface. This increases the magnetic anisotropy of the ferromagnetic portion 72 in the longitudinal direction of the inclined surface 203e (direction parallel to the X direction). As a result, the strength of the magnetic field applied to the MR element 50 located forward of the magnetic field generator 70 in the X direction or the −X direction is increased.

Note that in a case where the inclined surface 203e is a plane, when the magnetic moments in the plurality of parts 720 are directed to the direction parallel to the YZ plane and along the inclined surface, the direction of the magnetic moment in each of the plurality of parts 720 coincides or substantially coincides with each other. In this case, no or almost no difference in the energy of the exchange interaction thus occurs between the case where the magnetic moments in the plurality of parts 720 are directed to the direction parallel to the YZ plane and along the inclined surface 203e and the case where the magnetic moments in the plurality of parts 720 are directed to the longitudinal direction of the inclined surface 203e (direction parallel to the X direction). As a result, in this case, it is unlikely that the effect of increasing the magnetic anisotropy of the ferromagnetic portion 72 in the longitudinal direction of the inclined surface 203e (direction parallel to the X direction) occurs. [Modification Examples]

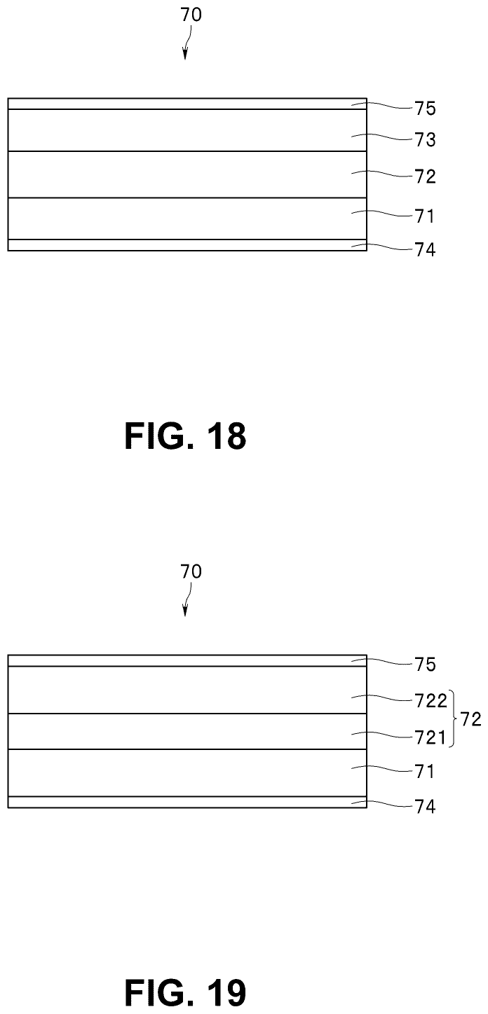

Next, first to fourth modification examples of the magnetic field generator 70 of the example embodiment will be described. The first modification example will initially be described with reference to FIG. 18. FIG. 18 is a side view showing the first modification example of the magnetic field generator 70. In the first modification example, the magnetic field generator 70 further includes an antiferromagnetic portion 73. The antiferromagnetic portion 73 is disposed at a position where the ferromagnetic portion 72 is interposed between the antiferromagnetic portion 73 and the antiferromagnetic portion 71. The antiferromagnetic portion 73 is formed of an antiferromagnetic material such as IrMn and PtMn. In the magnetic field generator 70 of the first modification example, the antiferromagnetic portion 71 and the antiferromagnetic portion 73 are exchange-coupled with the ferromagnetic portion 72 to thereby define the magnetization direction of the ferromagnetic portion 72.

In the first modification example, the magnetic field generator 70 further includes a buffer layer 74 and a cap layer 75. The buffer layer 74 is disposed at a position where the antiferromagnetic portion 71 is interposed between the buffer layer 74 and the ferromagnetic portion 72. The cap layer 75 is disposed at a position where the antiferromagnetic portion 73 is interposed between the cap layer 75 and the ferromagnetic portion 72. Each of the buffer layer 74 and the cap layer 75 are formed of a nonmagnetic metallic material such as Ru, Ta, Cu, and Cr, for example.

Next, the second modification example will be described with reference to FIG. 19. FIG. 19 is a side view showing the second modification example of the magnetic field generator 70. In the second modification example, the ferromagnetic portion 72 of the magnetic field generator 70 includes a ferromagnetic layer 721 and a ferromagnetic layer 722. Similar to the first modification example, the magnetic field generator 70 includes the buffer layer 74 and the cap layer 75. The buffer layer 74, the antiferromagnetic portion 71, the ferromagnetic layer 721, the ferromagnetic layer 722, and the cap layer 75 are stacked in this order. The ferromagnetic layers 721 and 722 are each formed of a ferromagnetic material containing one or more elements selected from Co, Fe, and Ni. In the second modification example, the ferromagnetic layer 721 and the ferromagnetic layer 722 each have magnetization in the same direction.

In the second modification example, the ferromagnetic layer 721 may be formed of a ferromagnetic material capable of increasing the exchange coupling energy with the antiferromagnetic portion 71, and the ferromagnetic layer 722 may be formed of a ferromagnetic material having a saturation magnetic flux density larger than that of the ferromagnetic material constituting the ferromagnetic layer 721. In this case, the strength of the bias magnetic field generated by the magnetic field generator 70 can be increased while increasing the exchange coupling energy between the ferromagnetic portion 72 including the ferromagnetic layers 721 and 722 and the antiferromagnetic portion 71, and the magnetic field generator 70 can be made smaller. Examples of the ferromagnetic layer 721 include a Co₇₀Fe₃₀ layer. Examples of the ferromagnetic layer 722 include a Co₃₀Fe₇₀ layer. Note that Co₇₀Fe₃₀ represents an alloy containing 70 atomic percent Co and 30 atomic percent Fe, and Co₃₀Fe₇₀ represents an alloy containing 30 atomic percent Co and 70 atomic percent Fe.

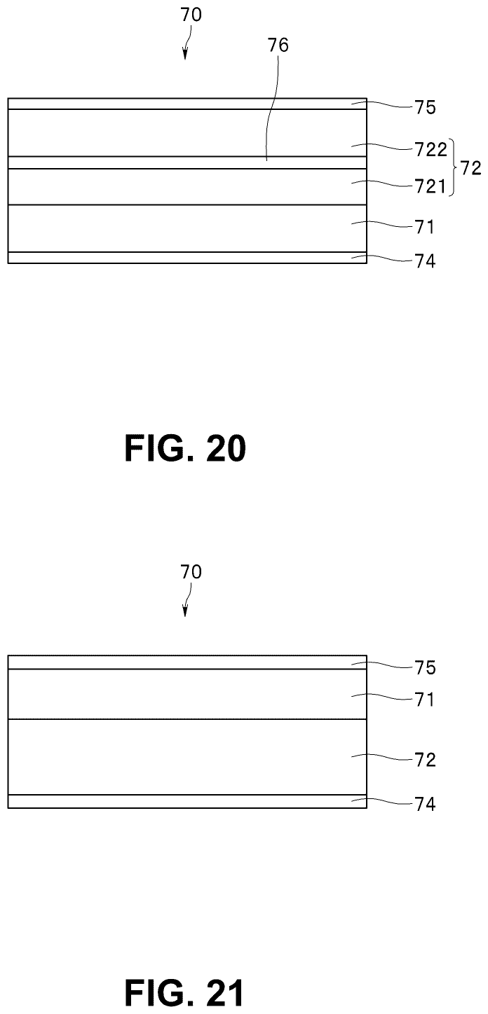

Next, the third modification example will be described with reference to FIG. 20. FIG. 20 is a side view showing the third modification example of the magnetic field generator 70. In the third modification example, the ferromagnetic portion 72 of the magnetic field generator 70 includes a ferromagnetic layer 721 and a ferromagnetic layer 722. Furthermore, similar to the first modification example, the magnetic field generator 70 includes the buffer layer 74 and the cap layer 75. The magnetic field generator 70 further includes a nonmagnetic layer 76. The buffer layer 74, the antiferromagnetic portion 71, the ferromagnetic layer 721, the nonmagnetic layer 76, the ferromagnetic layer 722, and the cap layer 75 are stacked in this order. The ferromagnetic layers 721 and 722 are each formed of a ferromagnetic material containing one or more elements selected from Co, Fe, and Ni. The ferromagnetic layer 721 and the ferromagnetic layer 722 may be formed of the same ferromagnetic material, or may be formed of different ferromagnetic materials. The nonmagnetic layer 76 is formed of a nonmagnetic metallic material such as Ru, for example.

In the third modification example, the ferromagnetic layer 721 and the ferromagnetic layer 722 may be ferromagnetically exchange-coupled with each other via the nonmagnetic layer 76 so that the magnetization directions of the ferromagnetic layer 721 and the ferromagnetic layer 722 are the same. In this case, the ferromagnetic layer 721 and the ferromagnetic layer 722 have magnetization in the same direction. The thickness of the nonmagnetic layer 76 is set to a thickness so that the exchange coupling between the ferromagnetic layer 721 and the ferromagnetic layer 722 is not lost. Providing the nonmagnetic layer 76 enables to adjust the coercivity of the ferromagnetic portion 72 and adjust the surface roughness of the base of the ferromagnetic layer 722.

Alternatively, the ferromagnetic layer 721 and the ferromagnetic layer 722 may be antiferromagnetically exchange-coupled with each other via the nonmagnetic layer 76 by the RKKY interaction. In this case, the magnetization direction of the ferromagnetic layer 721 and the magnetization direction of the ferromagnetic layer 722 are opposite to each other. The magnetization direction of the ferromagnetic portion 72 is the same as the magnetization direction of the ferromagnetic layer 721. When the ferromagnetic layer 721 and the ferromagnetic layer 722 are antiferromagnetically exchange-coupled with each other, the net moment of the ferromagnetic portion 72 becomes small. Therefore, in the ferromagnetic portion 72, the Zeeman energy, which is the energy generated by the external magnetic field acting on the magnetic moment, becomes small. As a result, even when an external magnetic field is applied, the magnetization direction of the ferromagnetic portion 72 is less likely to incline than when the Zeeman energy is large.

The thickness of the nonmagnetic layer 76 is set so that the respective magnetization directions of the ferromagnetic layer 721 and the ferromagnetic layer 722 due to the RKKY interaction become expected directions, and the strength of the exchange coupling by the RKKY interaction becomes an expected strength.

Next, the fourth modification example will be described with reference to FIG. 21. FIG. 21 is a side view showing the fourth modification example of the magnetic field generator 70. In the fourth modification example, similar to the first modification example, the magnetic field generator 70 includes the buffer layer 74 and the cap layer 75. The buffer layer 74, the antiferromagnetic portion 71, the ferromagnetic portion 72, and the cap layer 75 of the magnetic field generator 70 are stacked in the order of the buffer layer 74, the ferromagnetic portion 72, the antiferromagnetic portion 71, and the cap layer 75.

### Second Example Embodiment

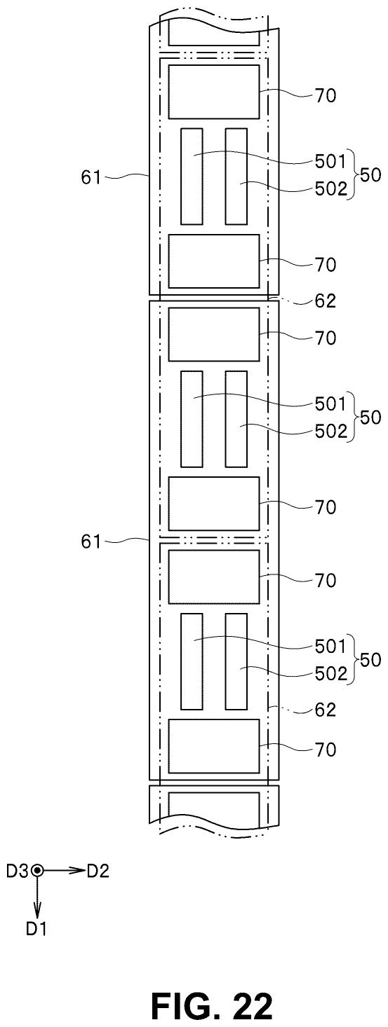

A second example embodiment of the disclosure will now be described with reference to FIG. 22. FIG. 22 is a plan view showing MR elements 50 and magnetic field generators 70 of the example embodiment.

In the example embodiment, each of the plurality of MR elements 50 includes a plurality of stacked films. Each of the plurality of stacked films has the same configuration as that of the MR element 50 of the first example embodiment. In the example shown in FIG. 22, the MR element 50 may include two stacked films 501 and 502. The two stacked films 501 and 502 are located between two adjacent magnetic field generators 70 in the first direction D1. The two stacked films 501 and 502 are connected in parallel by a lower electrode 61 and an upper electrode 62.

Here, of the plurality of stacked films included in each of the plurality of MR elements 50, one located at the end in the second direction D2 will be referred to as a first specific stacked film, and one located at the end in the direction opposite to the second direction D2 will be referred to as a second specific stacked film. The dimension of the magnetic field generator 70 in a direction parallel to the second direction D2 is greater than a distance from the end portion of the first specific stacked film in the second direction D2 to the end portion of the second specific stacked film in the direction opposite to the second direction D2.

If the MR element 50 shown in FIG. 22 is a first MR element 50A, the two stacked films 501 and 502 are arranged in a direction intersecting the longitudinal direction (X direction) of the first inclined surface 203a (see FIGS. 8 and 9). If the MR element 50 shown in FIG. 22 is a second MR element 50B, the two stacked films 501 and 502 are arranged in a direction intersecting the longitudinal direction (X direction) of the second inclined surface 203b (see FIGS. 8 and 9).

The configuration, operation, and effects of the example embodiment are otherwise the same as those of the first example embodiment.

### Third Example Embodiment

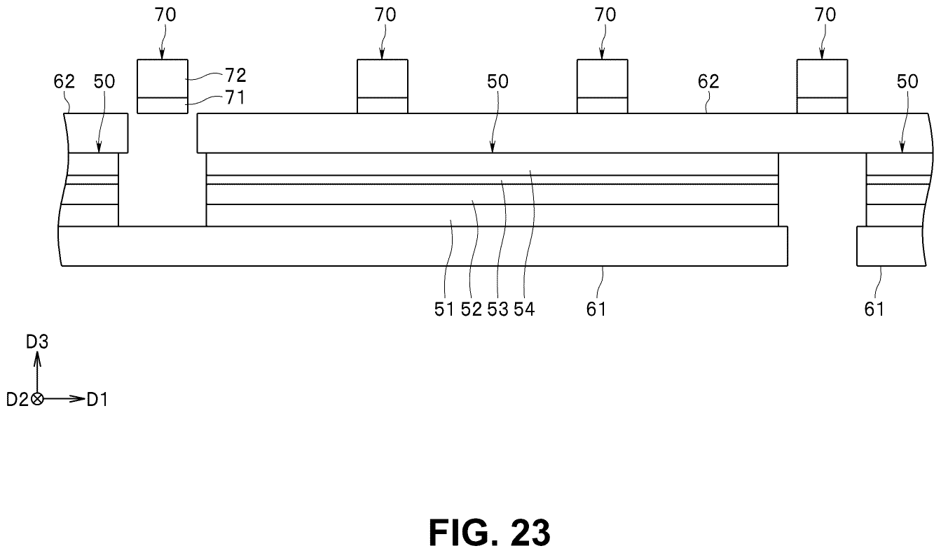

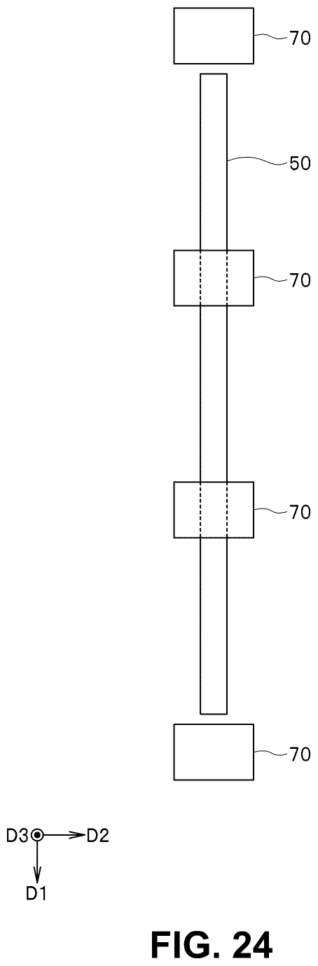

A third example embodiment of the disclosure will now be described with reference to FIGS. 23 and 24. FIG. 23 is a side view showing MR elements 50 and magnetic field generators 70 of the example embodiment. FIG. 24 is a plan view showing the MR element 50 and the magnetic field generators 70 of the example embodiment.

In the example embodiment, the plurality of magnetic field generators 70 are located above the MR elements 50. In the example shown in FIG. 23, some of the plurality of magnetic field generators 70 are in contact with the upper electrode 62, and some other of the plurality of magnetic field generators 70 are not in contact with the upper electrode 62. However, all of the magnetic field generators 70 may not need to be in contact with the upper electrode 62.

The MR element 50 is disposed between two specific magnetic field generators 70 located at positions away from each other in the first direction D1. At least one other magnetic field generator 70 is disposed between the two specific magnetic field generators 70. In the example shown in FIGS. 23 and 24, the number of the other magnetic field generators 70 is two. When seen from above, the other magnetic field generators 70 overlap with the MR element 50. When seen from above, the two specific magnetic field generators 70 may or may not overlap with the MR element 50.

The configuration, operation, and effects of the example embodiment are otherwise the same as those of the first or second example embodiment.

### Fourth Example Embodiment

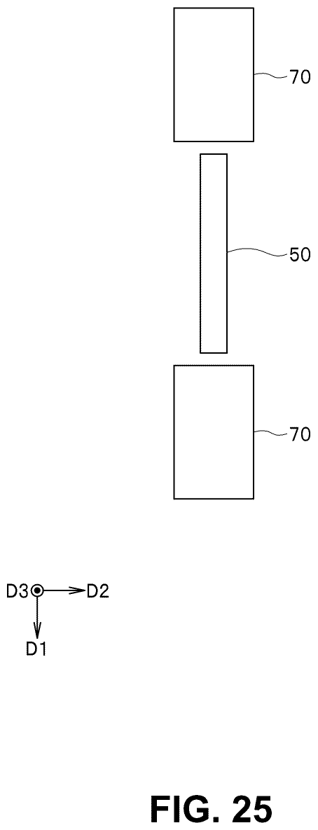

A fourth example embodiment of the disclosure will now be described with reference to FIG. 25. FIG. 25 is a plan view showing an MR element 50 and magnetic field generators 70 of the example embodiment.

In the example embodiment, the dimension of the magnetic field generator 70 in the direction parallel to the second direction D2 is smaller than the dimension of the magnetic field generator 70 in the direction parallel to the first direction D1. The configuration, operation, and effects of the example embodiment are otherwise the same as those of any of the first to third example embodiments.

### Fifth Example Embodiment

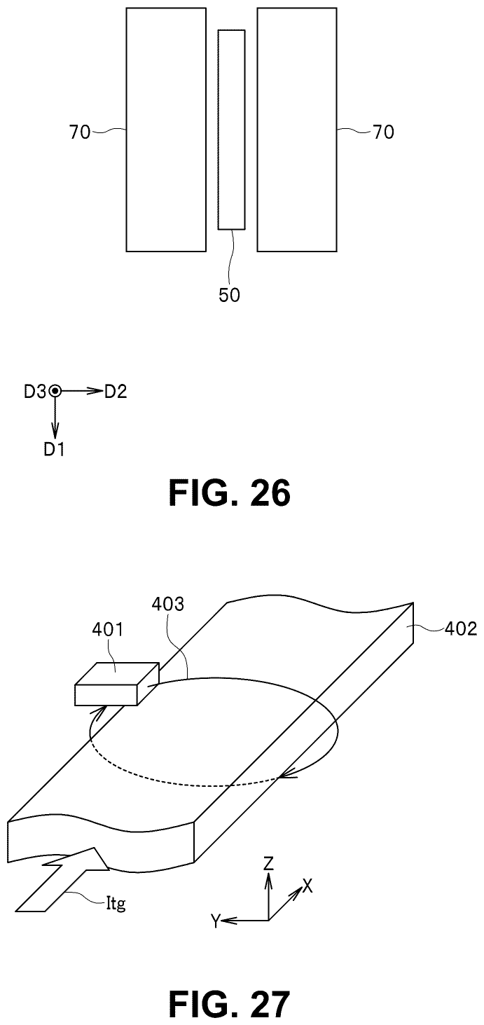

A fifth example embodiment of the disclosure will now be described with reference to FIG. 26. FIG. 26 is a plan view showing an MR element 50 and magnetic field generators 70 of the example embodiment.

In the example embodiment, each of the plurality of MR elements 50 is disposed between two adjacent magnetic field generators 70 in the second direction D2. The dimension of the magnetic field generator 70 in the direction parallel to the first direction D1 is greater than the dimension of the MR element 50 in the direction parallel to the first direction D1.

If the MR element 50 shown in FIG. 26 is a first MR element 50A and the magnetic field generators 70 shown in FIG. 26 are first magnetic field generators 70A, the two first magnetic field generators 70A on both sides of the first MR element 50A in the direction parallel to the second direction D2 are both located above one first inclined surface 203a (see FIG. 10).

If the MR element 50 shown in FIG. 26 is a second MR element 50B and the magnetic field generators 70 shown in FIG. 26 are second magnetic field generators 70B, the two second magnetic field generators 70B on both sides of the second MR element 50B in the direction parallel to the second direction D2 are both located above one second inclined surface 203b (see FIG. 10).

The configuration, operation, and effects of the example embodiment are otherwise the same as those of the first or second example embodiment.

### Sixth Example Embodiment

A sixth example embodiment of the disclosure will now be described with reference to FIG. 27. FIG. 27 is a perspective view showing a configuration of a current sensor system including a magnetic sensor according to the example embodiment.

A magnetic sensor 401 according to the example embodiment is used as a current sensor for detecting the value of a current to be detected flowing through a conductor. FIG. 27 shows an example in which the conductor through which the current to be detected flows is a bus bar 402. The magnetic sensor 401 is disposed near the bus bar 402. Hereinafter, the current to be detected will be referred to as target current Itg. The target current Itg generates a magnetic field 403 around the bus bar 402. The magnetic sensor 401 is disposed at a position where the magnetic field 403 is applied. In the example embodiment, the target magnetic field may be the magnetic field 403.

In the example embodiment, an X direction, a Y direction, and a Z direction will be defined as shown in FIG. 27. In FIG. 27, the direction in which the target current Itg flows is the X direction.

In particular, in the example embodiment, the magnetic sensor 401 is located at a position where a component of the magnetic field 403 in the Y direction and a component of the magnetic field 403 in the Z direction can be detected. The magnetic sensor 401 has the same configuration as that of the first chip 2 of the first example embodiment.

Note that the magnetic sensor 401 may have the same configuration as that of the second chip 3 of the first example embodiment. In such a case, the magnetic sensor 401 is located at a position where a component of the magnetic field 403 in the X direction can be detected.

The configuration, operation, and effects of the example embodiment are otherwise the same as those of any of the first to fifth example embodiments.

Note that the disclosure is not limited to the foregoing example embodiments, and various modifications may be made thereto. For example, the magnetic sensor of the disclosure may be configured of a plurality of chips integrated into one.

Furthermore, the first and second inclined surfaces 203a and 203b may be configured of a plurality of planes that are continuous with each other and have different angles with respect to the top surface 201a of the substrate 201.

As described above, a magnetic sensor according to one embodiment of the disclosure includes a support member having at least one inclined surface inclined with respect to a reference plane; at least one magnetic detection element disposed on the at least one inclined surface and configured to detect a target magnetic field; and at least one magnetic field generator disposed on the at least one inclined surface and configured to generate a magnetic field to be applied to the at least one magnetic detection element. The at least one magnetic field generator includes a ferromagnetic portion formed of a ferromagnetic material and an antiferromagnetic portion that is formed of an antiferromagnetic material and is exchange-coupled with the ferromagnetic portion. The ferromagnetic portion and the antiferromagnetic portion are stacked together in a direction intersecting the at least one inclined surface. An angle that the at least one inclined surface forms with respect to the reference plane at any given point on the at least one inclined surface changes depending on a position of the any given point in a direction perpendicular to the reference plane.

In the magnetic sensor according to one embodiment of the disclosure, a thickness of the ferromagnetic portion in a direction perpendicular to the at least one inclined surface may be smaller than a thickness of the at least one magnetic detection element in the direction perpendicular to the at least one inclined surface. The at least one magnetic detection element may be at least one magnetoresistive element. The at least one magnetoresistive element may include a magnetization pinned layer whose magnetization direction is fixed, and a free layer whose magnetization direction is variable depending on the target magnetic field. The thickness of the ferromagnetic portion in the direction perpendicular to the at least one inclined surface may be greater than a thickness of the free layer in the direction perpendicular to the at least one inclined surface.

In the magnetic sensor according to one embodiment of the disclosure, the at least one inclined surface may be a curved surface.

In the magnetic sensor according to one embodiment of the disclosure, each of the ferromagnetic portion and the antiferromagnetic portion may have a bottom surface that faces the at least one inclined surface and is inclined with respect to the reference plane.

In the magnetic sensor according to one embodiment of the disclosure, the at least one magnetic detection element may have a first bottom surface having a shape along the at least one inclined surface. The at least one magnetic field generator may have a second bottom surface having a shape that is along the at least one inclined surface and substantially same as the shape of the first bottom surface at least in part.

In the magnetic sensor according to one embodiment of the disclosure, the at least one inclined surface may have a shape long in a direction parallel to the reference plane when seen in the direction perpendicular to the reference plane. The at least one magnetic field generator may include a plurality of magnetic field generators disposed along a longitudinal direction of the at least one inclined surface.

In the magnetic sensor according to one embodiment of the disclosure, the at least one magnetic field generator may include a first magnetic field generator and a second magnetic field generator. The ferromagnetic portion of the first magnetic field generator may have a first magnetization. The ferromagnetic portion of the second magnetic field generator may have a second magnetization. The first magnetization may include a component in a first direction. The second magnetization may include a component in a second direction different from the first direction. The at least one inclined surface may include a first inclined surface and a second inclined surface. The first magnetic field generator may be disposed on the first inclined surface. The second magnetic field generator may be disposed on the second inclined surface.

In the magnetic sensor according to one embodiment of the disclosure, the at least one inclined surface may include a specific inclined surface directed to a direction inclined with respect to both the reference plane and the direction perpendicular to the reference plane. The specific inclined surface may have a shape long in a direction parallel to the reference plane when seen in the direction perpendicular to the reference plane. The at least one magnetic detection element may include two stacked films disposed on the specific inclined surface and arranged along a direction intersecting a longitudinal direction of the specific inclined surface.

The magnetic sensor according to one embodiment of the disclosure may further include a power supply port; a ground port; a first output port; a second output port; a first resistor section provided between the power supply port and the first output port; a second resistor section provided between the ground port and the first output port; a third resistor section provided between the ground port and the second output port; and a fourth resistor section provided between the power supply port and the second output port. The at least one magnetic detection element may include a plurality of first magnetic detection elements disposed in a first area and constituting the first resistor section, a plurality of second magnetic detection elements disposed in a second area and constituting the second resistor section, a plurality of third magnetic detection elements disposed in a third area and constituting the third resistor section, and a plurality of fourth magnetic detection elements disposed in a fourth area and constituting the fourth resistor section. The at least one magnetic field generator may include a plurality of magnetic field generators. The plurality of magnetic field generators may be disposed dividedly in the first area, the second area, the third area, and the fourth area. The ferromagnetic portion of each of the plurality of magnetic field generators disposed in two of the first area, the second area, the third area, and the fourth area may have a first magnetization. The ferromagnetic portion of each of the plurality of magnetic field generators disposed in other two of the first area, the second area, the third area, and the fourth area may have a second magnetization. The first magnetization may include a component in a first direction. The second magnetization may include a component in a second direction opposite to the first direction.

In the magnetic sensor according to one embodiment of the disclosure, the at least one inclined surface may include a first inclined surface and a second inclined surface each having a shape long in a direction parallel to the reference plane when seen in the direction perpendicular to the reference plane, the first inclined surface and the second inclined surface being directed to respective different directions. The at least one magnetic detection element may include a plurality of first magnetic detection elements disposed on the first inclined surface and a plurality of second magnetic detection elements disposed on the second inclined surface. The at least one magnetic field generator may include a plurality of first magnetic field generators disposed on the first inclined surface and a plurality of second magnetic field generators disposed on the second inclined surface. The plurality of first magnetic detection elements may constitute a first detection circuit configured to detect a component of the target magnetic field in a first direction inclined with respect to both the reference plane and the direction perpendicular to the reference plane and generate a first detection signal. The plurality of second magnetic detection elements may constitute a second detection circuit configured to detect a component of the target magnetic field in a second direction inclined with respect to both the reference plane and the direction perpendicular to the reference plane and generate a second detection signal. The magnetic sensor according to one embodiment of the disclosure may further include another support member having a flat surface; a plurality of third magnetic detection elements disposed on the flat surface; and a plurality of third magnetic field generators disposed on the flat surface and configured to generate a magnetic field to be applied to the plurality of third magnetic detection elements. The plurality of third magnetic detection elements may constitute a third detection circuit configured to detect a component of the target magnetic field in a third direction parallel to the reference plane and generate a third detection signal. The target magnetic field may be a geomagnetism.

In the magnetic sensor according to one embodiment of the disclosure, the target magnetic field may be a magnetic field generated by a current to be detected flowing through a conductor.

In the magnetic sensor of the disclosure, the angle that the at least one inclined surface forms with respect to the reference plane at the any given point on the at least one inclined surface changes depending on the position of the any given point in the direction perpendicular to the reference plane. Therefore, according to the disclosure, the magnetic sensor capable of increasing the strength of the magnetic field applied to the magnetic detection element by the magnetic field generator can be implemented.

It is apparent that the disclosure can be carried out in various forms and modification examples in the light of the foregoing descriptions. Accordingly, within the scope of the following claims and equivalents thereof, the disclosure can be carried out in forms other than the foregoing example embodiments.

1. A magnetic sensor comprising:
a support member having at least one inclined surface inclined with respect to a reference plane;
at least one magnetic detection element disposed on the at least one inclined surface and configured to detect a target magnetic field; and
at least one magnetic field generator disposed on the at least one inclined surface and configured to generate a magnetic field to be applied to the at least one magnetic detection element, wherein:
the at least one magnetic field generator includes a ferromagnetic portion formed of a ferromagnetic material and an antiferromagnetic portion that is formed of an antiferromagnetic material and is exchange-coupled with the ferromagnetic portion;
the ferromagnetic portion and the antiferromagnetic portion are stacked together in a direction intersecting the at least one inclined surface; and
an angle that the at least one inclined surface forms with respect to the reference plane at any given point on the at least one inclined surface changes depending on a position of the any given point in a direction perpendicular to the reference plane.

2. The magnetic sensor according to claim 1, wherein a thickness of the ferromagnetic portion in a direction perpendicular to the at least one inclined surface is smaller than a thickness of the at least one magnetic detection element in the direction perpendicular to the at least one inclined surface.

3. The magnetic sensor according to claim 2, wherein:
the at least one magnetic detection element is at least one magnetoresistive element;
the at least one magnetoresistive element includes a magnetization pinned layer whose magnetization direction is fixed, and a free layer whose magnetization direction is variable depending on the target magnetic field; and
the thickness of the ferromagnetic portion in the direction perpendicular to the at least one inclined surface is greater than a thickness of the free layer in the direction perpendicular to the at least one inclined surface.

4. The magnetic sensor according to claim 1, wherein the at least one inclined surface is a curved surface.

5. The magnetic sensor according to claim 1, wherein each of the ferromagnetic portion and the antiferromagnetic portion has a bottom surface that faces the at least one inclined surface and is inclined with respect to the reference plane.

6. The magnetic sensor according to claim 1, wherein:
the at least one magnetic detection element has a first bottom surface having a shape along the at least one inclined surface; and
the at least one magnetic field generator has a second bottom surface having a shape that is along the at least one inclined surface and substantially same as the shape of the first bottom surface at least in part.

7. The magnetic sensor according to claim 1, wherein:
the at least one inclined surface has a shape long in a direction parallel to the reference plane when seen in the direction perpendicular to the reference plane; and
the at least one magnetic field generator includes a plurality of magnetic field generators disposed along a longitudinal direction of the at least one inclined surface.

8. The magnetic sensor according to claim 1, wherein:
the at least one magnetic field generator includes a first magnetic field generator and a second magnetic field generator;
the ferromagnetic portion of the first magnetic field generator has a first magnetization;
the ferromagnetic portion of the second magnetic field generator has a second magnetization;
the first magnetization includes a component in a first direction; and
the second magnetization includes a component in a second direction different from the first direction.

9. The magnetic sensor according to claim 8, wherein:
the at least one inclined surface includes a first inclined surface and a second inclined surface;
the first magnetic field generator is disposed on the first inclined surface; and
the second magnetic field generator is disposed on the second inclined surface.

10. The magnetic sensor according to claim 1, wherein:
the at least one inclined surface includes a specific inclined surface directed to a direction inclined with respect to both the reference plane and the direction perpendicular to the reference plane;
the specific inclined surface has a shape long in a direction parallel to the reference plane when seen in the direction perpendicular to the reference plane; and
the at least one magnetic detection element includes two stacked films disposed on the specific inclined surface and arranged along a direction intersecting a longitudinal direction of the specific inclined surface.

11. The magnetic sensor according to claim 1, further comprising:
a power supply port;
a ground port;
a first output port;
a second output port;
a first resistor section provided between the power supply port and the first output port;
a second resistor section provided between the ground port and the first output port;
a third resistor section provided between the ground port and the second output port; and
a fourth resistor section provided between the power supply port and the second output port, wherein:
the at least one magnetic detection element includes a plurality of first magnetic detection elements disposed in a first area and constituting the first resistor section, a plurality of second magnetic detection elements disposed in a second area and constituting the second resistor section, a plurality of third magnetic detection elements disposed in a third area and constituting the third resistor section, and a plurality of fourth magnetic detection elements disposed in a fourth area and constituting the fourth resistor section;
the at least one magnetic field generator includes a plurality of magnetic field generators;
the plurality of magnetic field generators are disposed dividedly in the first area, the second area, the third area, and the fourth area;
the ferromagnetic portion of each of the plurality of magnetic field generators disposed in two of the first area, the second area, the third area, and the fourth area has a first magnetization;
the ferromagnetic portion of each of the plurality of magnetic field generators disposed in other two of the first area, the second area, the third area, and the fourth area has a second magnetization;
the first magnetization includes a component in a first direction; and
the second magnetization includes a component in a second direction opposite to the first direction.

12. The magnetic sensor according to claim 1, wherein:
the at least one inclined surface includes a first inclined surface and a second inclined surface each having a shape long in a direction parallel to the reference plane when seen in the direction perpendicular to the reference plane, the first inclined surface and the second inclined surface being directed to respective different directions;
the at least one magnetic detection element includes a plurality of first magnetic detection elements disposed on the first inclined surface and a plurality of second magnetic detection elements disposed on the second inclined surface;
the at least one magnetic field generator includes a plurality of first magnetic field generators disposed on the first inclined surface and a plurality of second magnetic field generators disposed on the second inclined surface;
the plurality of first magnetic detection elements constitute a first detection circuit configured to detect a component of the target magnetic field in a first direction inclined with respect to both the reference plane and the direction perpendicular to the reference plane and generate a first detection signal; and
the plurality of second magnetic detection elements constitute a second detection circuit configured to detect a component of the target magnetic field in a second direction inclined with respect to both the reference plane and the direction perpendicular to the reference plane and generate a second detection signal.

13. The magnetic sensor according to claim 12, further comprising:
another support member having a flat surface;
a plurality of third magnetic detection elements disposed on the flat surface; and
a plurality of third magnetic field generators disposed on the flat surface and configured to generate a magnetic field to be applied to the plurality of third magnetic detection elements, wherein:
the plurality of third magnetic detection elements constitute a third detection circuit that detects a component of the target magnetic field in a third direction parallel to the reference plane and generates a third detection signal.

14. The magnetic sensor according to claim 13, wherein the target magnetic field is a geomagnetism.

15. The magnetic sensor according to claim 1, wherein the target magnetic field is a magnetic field generated by a current to be detected flowing through a conductor.
